(19) United States
(12) Patent Application Publication
(10) Pub. No.: US 2008/0213936 A1
(43) Pub. Date: Sep. 4, 2008

(54) Alignment mark forming method, alignment method, semiconductor device manufacturing method, and solid-state image capturing apparatus manufacturing method

(75) Inventor: Tetsuya Hatai, Fukuyama-shi (JP)

Correspondence Address: Edwards Angell Palmer & Dodge LLP, P. O. Box 55874, Boston, MA, 02205, US

(73) Assignee: Sharp Kabushiki Kaisha, Osaka (JP)

(21) Appl. No.: 12/009,982

(22) Filed: Jan. 23, 2008

(30) Foreign Application Priority Data
Jan. 23, 2007 (JP) 2007-012935

(51) Int. Cl. H01L 31/00; H01L 21/425

(52) U.S. Cl. 438/60; 438/531; 257/E31.001; 257/E21.473

(57) ABSTRACT

An alignment mark forming method according to the present invention includes: an alignment mark forming step of using an impurity implantation region as an alignment target layer and using, as a mask, the same resist film used for forming the impurity implantation region to form an alignment mark that is used when a patterning is performed in at least one of a subsequent impurity implantation step and a subsequent process layer forming step.

This Nonprovisional application claims priority under 35 U.S.C. §119(a) on Patent Application No. 2007-012935 filed in Japan on Jan. 23, 2007, the entire contents of which are hereby incorporated by reference.

### BACKGROUND OF THE INVENTION

1. Field of the Invention

The present invention relates to: an alignment mark forming method in which an impurity implantation region can be used as an alignment target layer in order to reduce a tolerance value in alignment precision between impurity implantation regions and also to reduce a tolerance value in alignment precision between an impurity implantation region and a process layer (e.g., wiring layer, light-shielding film or the like) formed in a step subsequent to an impurity implantation step among steps of manufacturing a semiconductor device (e.g. ,transistor, photodiode and the like); an alignment method using the alignment mark forming method; and a semiconductor device manufacturing method and a solid-state image capturing apparatus manufacturing method for manufacturing a semiconductor device and a solid-state image capturing apparatus by performing an alignment using an alignment mark formed by using the alignment mark forming method.

2. Description of the Related Art

Conventionally, in the steps of manufacturing a semiconductor device and in the steps of manufacturing a solid-state image capturing apparatus of this kind, a lithography step is performed, in which a photo-resist film is exposed to light and a predetermined photo-resist pattern is formed in order to form an impurity implantation region. Generally, when the lithography step is performed, an alignment mark processed in a first layer in a manufacturing process for the main purpose of forming an alignment mark, an alignment mark using an oxide film (e.g., STI (Shallow Trench Isolation), LOCOS (Local Oxidation of Silicon) and the like) formed for element separation, an alignment mark formed at the same time as processing a poly-silicon gate or the like is used as an alignment mark. An alignment is performed using, as a target layer, a layer having the alignment mark formed therein, and a photo-resist pattern is resolved.

References 1 and 2 disclose, for example, a device in a semiconductor device and a solid-state image capturing apparatus in which elements are separated with an impurity implantation region in order to improve leak current generated due to high-integration and unconformity of the interface between a silicon oxide film used for element separation and a silicon substrate.

In a conventional solid-state image capturing apparatus disclosed in Reference 1, impurity is implanted into a boundary portion between pixel sections to form a plurality of layers of well regions for element separation.

In a conventional solid-state image capturing apparatus disclosed in Reference 2, impurity is implanted between vertical transfer channels adjacent to each other to form an element separation region.

As described above, alignment precision between impurity implantation regions is becoming more important in further improving high integration and high functionality of a device in which elements are separated with an impurity implantation region.

Reference 1: Japanese Laid-Open Publication No. 2004-56017

Reference 2: Japanese Laid-Open Publication No. 2003-258232

### SUMMARY OF THE INVENTION

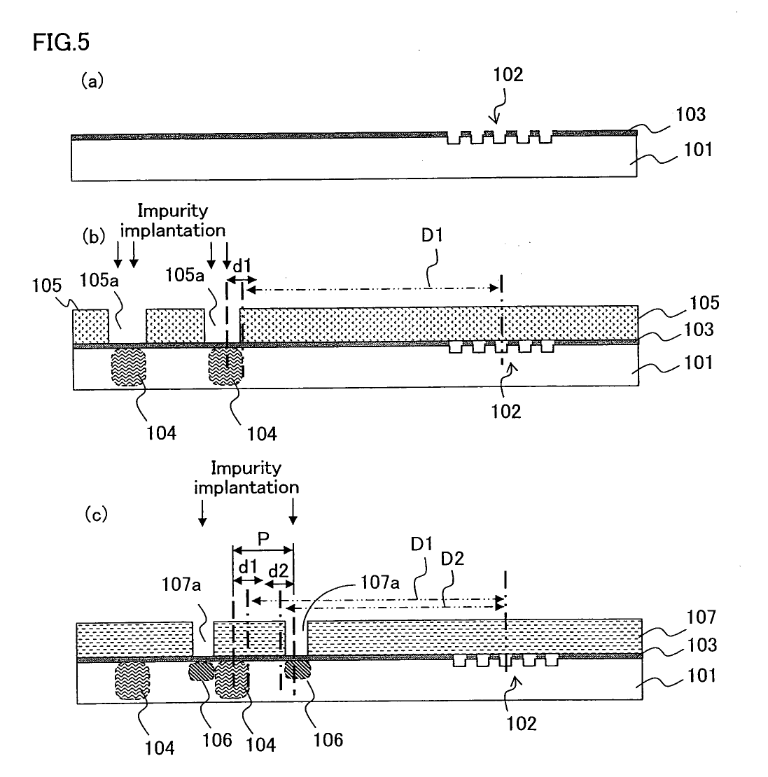

However, in the case where such a device in which elements are separated with an impurity implantation region described above is manufactured, when an alignment mark formed by a conventional alignment mark forming method is used, a problem occurs in which alignment precision between impurity implantation regions cannot be improved. Hereinafter, this problem will be described in detail with reference to Portion (a) of FIG. 5 to Portion (c) of FIG. 5.

Portion (a) of FIG. 5 to Portion (c) of FIG. 5 are each a longitudinal cross-sectional view showing a step of manufacturing a conventional semiconductor device for describing the problem of an alignment mark formed by the conventional alignment mark forming method.

First, as shown in Portion (a) of FIG. 5, an alignment mark 102 is formed in a semiconductor substrate 101 by the conventional alignment mark forming method. Numeral reference 103 indicates an impurity implantation protecting film.

Next, as shown in Portion (b) of FIG. 5, in order to form an impurity implantation region 104 in the semiconductor substrate 101, a photo-resist film is coated on a semiconductor substrate portion where the alignment mark 102 and the impurity implantation protecting film 103 are formed, and a predetermined impurity implantation preventing photo-resist pattern 105 is formed using the alignment mark 102 such that an opening 105a is positioned above a region for becoming the impurity implantation region 104. The impurity implantation preventing photo-resist pattern 105 is used as a mask, and predetermined impurity ions are implanted through the opening 105a into a portion of the semiconductor substrate 101 that corresponds to the opening 105a to form the impurity implantation region 104.

Thereafter, as shown Portion (c) of FIG. 5, in order to further form an impurity implantation region 106 in the semiconductor substrate 101, a photo-resist film is coated on the semiconductor substrate portion where the alignment mark 102 and the impurity implantation protecting film 103 are formed, and a predetermined impurity implantation preventing photo-resist pattern 107 is formed using the alignment mark 102 such that an opening 107a is positioned above a region for becoming the impurity implantation region 106.

The impurity implantation preventing photo-resist pattern 107 is used as a mask, and predetermined impurity ions are implanted through the opening 107a into a portion of the semiconductor substrate 101 that corresponds to the opening 107a to form the impurity implantation region 106.

Herein, the positional relationship between the alignment mark 102 and the impurity implantation regions 104 and 106 will be described in further detail.

In Portion (b) of FIG. 5, D1 indicates a distance between the alignment mark 102 and the impurity implantation region 104. d1 indicates a misalignment tolerance range for the impurity implantation region 104. In Portion (c) of FIG. 5, D2 indicates a distance between the alignment mark 102 and the impurity implantation region 106. d2 indicates a misalignment tolerance range for the impurity implantation region 106.

In this case, it is assumed that the alignment precision with respect to the alignment mark 102 can be optimized in the lithography step of resolving the impurity implantation preventing photo-resist pattern 105 and the impurity implantation preventing photo-resist pattern 107.

The alignment precision for the impurity implantation region 106 can only be secured with the alignment mark 102 when the impurity implantation region 104 is taken into consideration. Therefore, in the case where the degree of misalignment between the impurity implantation region 104 and the impurity implantation region 106 is worst, as indicated by distance P in Portion (c) of FIG. 5, a value in misalignment between the impurity implantation region 104 and the impurity implantation region 106 is a value in which a misalignment tolerance range d1 for the impurity implantation region 104 and a misalignment tolerance range d2 for the impurity implantation region 106 are combined together.

As such, when the worst case is assumed, provided that the alignment precision is the misalignment tolerance region d1=the misalignment tolerance region d2, the value in misalignment between the impurity implantation region 104 and the impurity implantation region 106 is a value that is twice as much as the alignment precision (misalignment tolerance region d1). Therefore, in consideration of the misalignment twice as much as the alignment precision (misalignment tolerance range d1), it is necessary to secure the device characteristic of a semiconductor device or a solid-state image capturing apparatus.

Thus, even if an alignment mechanism in a exposure device (e.g., stepper) is controlled to the maximum, or an error recognition amount of alignment mark detection by the exposure device is controlled to the maximum by controlling a process shape of the alignment mark 102 to be formed in the semiconductor substrate 101, as long as an alignment is performed using the alignment mark 102 formed by the conventional alignment mark forming method, a semiconductor device or a solid-state image capturing apparatus has to be designed on the assumption that alignment precision is greater than or equal to twice the performance of the device or the apparatus. As a result, chip size in a product becomes large, and this causes a problem that the number of chips to be mounted on a semiconductor substrate is suppressed, which causes a higher manufacturing cost.

In order to address this problem, a method is conventionally performed, in which an alignment is directly performed on an impurity implantation region. In this case, in a lithography step of resolving an impurity implantation preventing photo-resist pattern, an alignment mark forming photo-resist pattern is formed in an alignment mark forming region, and an impurity implantation is performed. As a result, an alignment mark that is configured by a region with impurity implanted therein and a region with the implantation of impurity therein prevented is formed.

However, only with the implantation of impurity into a semiconductor layer, it is not possible to process and form a special difference between the region with the impurity implanted therein and the region with the implantation of impurity therein prevented. In an alignment method for detecting the position of the alignment mark using scattered light from a difference portion as a detection signal waveform with respect to incident light from a light source for alignment, and also in an alignment method for detecting the position of the alignment mark using, as a detection signal waveform, light/dark observed at an edge portion of a difference using an image viewed from above the alignment mark portion, no detection signal waveform appears due to the absence of difference. Therefore, these alignment methods cannot be used for an actual manufacturing process.

In addition, light/dark contrast or color contrast between the region with the impurity implanted therein and the region with the implantation of impurity therein prevented barely appears on a substrate surface. Thus, even in an alignment method for detecting the position of alignment mark using an alignment mark configured by a region with the impurity implanted therein and a region with the implantation of impurity therein prevented to utilize a light/dark contrast difference or a color contrast difference as a detection signal waveform, an alignment error occurs due to a weak detection signal waveform. As such, this alignment method cannot be used for an actual manufacturing process.

Further, a method can be considered in which after impurity is implanted, an impurity implantation preventing photo-resist pattern is used as a mask to process one or a plurality of groove portions for becoming an alignment mark in a semiconductor substrate.

However, in this case, although the one or the plurality of grooves for becoming the alignment mark can be processed, the one or the plurality of grooves is also formed in a semiconductor substrate region of an active region where no processing of groove is intended. As such, a required characteristic of semiconductor device or solid-state image capturing apparatus cannot be obtained.

Hence, as described above, alignment between impurity implantation regions or between an impurity implantation region and a process layer (e.g., wiring layer, light-shielding film or the like) formed in a step subsequent to an impurity implantation step is performed using an alignment mark formed in another substrate processing step, which causes a problem of managing and securing the alignment precision within a numeral range which is laxer than the limitation of the performance of an exposure device.

The problem in alignment between impurity implantation regions or between an impurity implantation region and a process layer formed in a step subsequent to an impurity implantation step is not obvious in a semiconductor device or a solid-state image capturing apparatus that uses a conventional large-size pattern. However, as a result of the progress of miniaturization of pattern size, this problem has become a more significant issue.

The present invention is intended to solve the conventional problems described above. The objective of the present invention is to provide: an alignment mark forming method that can use an impurity implantation region as a target layer to improve alignment precision in lithography (e.g., subsequent impurity region forming step, subsequent step of processing a wiring layer, a light-shielding layer or the like) even in a semiconductor device or a solid-state image capturing apparatus that uses a miniaturized pattern size so as to obtain a required device characteristic; an alignment method using the alignment mark forming method; and a semiconductor device manufacturing method and a solid-state image capturing apparatus manufacturing method for manufacturing a semiconductor device and a solid-state image capturing apparatus by performing an alignment using an alignment mark formed by using the alignment mark forming method.

An alignment mark forming method according to the present invention includes: an alignment mark forming step of using an impurity implantation region as an alignment target layer and using, as a mask, the same resist film used for forming the impurity implantation region to form an alignment mark that is used when a patterning is performed in at least one of a subsequent impurity implantation step and a subsequent process layer forming step, thereby the objective described above being achieved. Herein, the same resist film will be further described. An alignment mark forming method according to the present invention includes: an alignment mark forming step of using an impurity implantation region as an alignment target layer and using, as a mask, the same resist film used for forming the impurity implantation region to form an alignment mark that is used when a patterning is performed in at least one of a subsequent impurity implantation step and a subsequent process layer forming step, wherein the resist film includes a resist pattern for forming the alignment mark and a resist pattern for forming the impurity implantation region, the resist patterns being exposed to light and formed at the same time, thereby the objective described above being achieved.

Preferably, in an alignment mark forming method according to the present invention, prior to the formation of the alignment mark, the alignment mark forming step includes a protecting film forming step of forming a protecting film for protecting at least a top surface of a semiconductor substrate that corresponds to the impurity implantation region.

Still preferably, in an alignment mark forming method according to the present invention, the protecting film forming step includes: a protecting film coating step of coating an impurity implantation protecting film on the semiconductor substrate; and a protecting film removing step of removing the impurity implantation protecting film in an alignment mark forming region.

Still preferably, in an alignment mark forming method according to the present invention, the alignment mark forming step includes: a resist pattern forming step of coating a resist film on the semiconductor substrate, and forming an impurity implantation preventing resist pattern having an opening above an active region for becoming the impurity implantation region and forming an alignment mark forming resist pattern having one or a plurality of openings above a region for becoming the alignment mark; and prior to the impurity implantation step or subsequent to the impurity implantation step, a groove forming step of using, as a mask, the resist film having the impurity implantation preventing resist pattern and the alignment mark forming resist pattern formed therein to form one or a plurality of grooves as the alignment mark in an alignment mark forming region of the semiconductor substrate.

Still preferably, in an alignment mark forming method according to the present invention, the groove forming step forms a difference portion in the impurity implantation protecting film that corresponds to the impurity implantation preventing resist pattern.

Still preferably, in an alignment mark forming method according to the present invention, when the one or the plurality of grooves is formed, the semiconductor substrate in the impurity implantation region is covered with the impurity implantation protecting film.

Still preferably, in an alignment mark forming method according to the present invention, the alignment mark forming step includes: a protecting film coating step of coating an impurity implantation protecting film on a semiconductor substrate; a first resist pattern forming step of coating a resist film on the impurity implantation protecting film, and forming, in the resist film, an impurity implantation preventing resist pattern having an opening above an active region for becoming the impurity implantation region and forming an alignment mark forming resist pattern having one or a plurality of openings above a region for becoming the alignment mark; prior to the impurity implantation step or subsequent to the impurity implantation step, a difference portion forming step of using, as a mask, the resist film having the impurity implantation preventing resist pattern and the alignment mark forming resist pattern formed therein to remove a part or the entirety of the impurity implantation protecting film that corresponds to an opening of the resist film so as to form a difference portion in the impurity implantation protecting film; a resist film removing step of removing the resist film; a second resist pattern forming step of newly coating another resist film on the semiconductor substrate and forming, in the other resist film, an alignment mark region forming resist pattern having one or a plurality of openings above a region for becoming the alignment mark; and a groove forming step of using, as a mask, the resist film having the alignment mark region forming resist pattern formed therein and the impurity implantation protecting film having the alignment mark forming pattern formed therein to form one or a plurality of grooves as the alignment mark in an alignment mark forming region of the semiconductor substrate.

Still preferably, an alignment mark forming method according to the present invention further includes an insulating film forming step of forming an insulating layer on the semiconductor substrate for the purpose of separating elements, the alignment mark forming step includes: a protecting film coating step of coating an impurity implantation protecting film on the semiconductor substrate and the insulating layer; a resist pattern forming step of coating a resist film on the impurity implantation protecting film, and forming an impurity implantation preventing resist pattern having an opening above an active region for becoming the impurity implantation region and forming an alignment mark forming resist pattern having one or a plurality of openings above a region for becoming the alignment mark in the insulating layer that is formed in an alignment mark forming region in the insulating film forming step; and prior to the impurity implantation step or subsequent to the impurity implantation step, a groove forming step of using, as a mask, the resist film having the impurity implantation preventing resist pattern and the alignment mark forming resist pattern formed therein to selectively remove a part or the entirety of the impurity implantation protecting film that corresponds to an opening of the resist film and to remove a part of the insulating layer below the removed impurity implantation protecting film so as to form one or a plurality of groove portions for becoming the alignment mark.

Still preferably, an alignment mark forming method according to the present invention further includes an insulating film forming step of forming an insulating layer on the semiconductor substrate for the purpose of separating elements, the alignment mark forming step includes: a resist pattern forming step of coating a resist film on the semiconductor substrate, and forming an impurity implantation preventing resist pattern having an opening above an active region for becoming the impurity implantation region and forming an alignment mark forming resist pattern having one or a plurality of openings above a region for becoming the alignment mark in the insulating layer that is formed in an alignment mark forming region in the insulating layer forming step; and prior to the impurity implantation step or subsequent to the impurity implantation step, a groove forming step of using, as a mask, the resist film having the impurity implantation preventing resist pattern and the alignment mark forming resist pattern formed therein to remove a part of the insulating layer that corresponds to an opening of the resist film so as to form one or a plurality of grooves for becoming the alignment mark.

Still preferably, in an alignment mark forming method according to the present invention, at least one of an oxide film and a nitride film is coated as the impurity implantation protecting film.

Still preferably, in an alignment mark forming method according to the present invention, at least one of an oxide film and a nitride film is coated as the insulating film.

Still preferably, in an alignment mark forming method according to the present invention, the resist film is set so as to have a film thickness that is required to prevent a penetration of impurity when the impurity is implanted.

Still preferably, in an alignment mark forming method according to the present invention, the impurity implantation protecting film is coated so as to have a film thickness such that an etching be completed within the impurity implantation protecting film in the groove forming step or in the difference portion forming step.

Still preferably, in an alignment mark forming method according to the present invention, the impurity implantation protecting film is coated so as to have a film thickness such that the film thickness of the impurity implantation protecting film does not affect the semiconductor substrate nor a device characteristic even if the impurity implantation protecting film is removed in the groove forming step or in the difference portion forming step and thus becomes thinner.

Still preferably, in an alignment mark forming method according to the present invention, the impurity implantation protecting film is coated such that a film thickness thereof is between 50 Å (including 50 Å) and 2000 Å (including 2000 Å).

Still preferably, in an alignment mark forming method according to the present invention, an etching condition is set such that a film thickness of the impurity implantation protecting film to be removed is between 10% (including 10%) and 100% (including 100%) of the entire film thickness of the impurity implantation protecting film.

Still preferably, in an alignment mark forming method according to the present invention, the formation of the difference portion in the impurity implantation protecting film is performed by a wet etching technique and/or a dry etching technique such that a sufficient difference in etching rate between the impurity implantation protecting film and the semiconductor substrate is obtained, a type, concentration and liquid immersion time of an etching liquid are set in the wet etching technique, and a vacuum degree, a gas mixing ratio, a gas flow volume and a plasma-applied voltage are set in the dry etching technique.

Still preferably, in an alignment mark forming method according to the present invention, after the formation of the alignment mark, the entire impurity implantation protecting film is removed from the semiconductor substrate, and an impurity implantation protecting film is newly coated for a subsequent impurity implantation step.

Still preferably, in an alignment mark forming method according to the present invention, the second resist pattern forming step exposes to light and develops the alignment mark forming region to form a pattern in the other resist film and uses, as a mask, the other resist film having the resolved alignment mark forming pattern to expose the alignment mark forming pattern formed in the impurity implantation protecting film.

Still preferably, in an alignment mark forming method according to the present invention, the second resist pattern forming step forms the other resist pattern such that it covers the semiconductor substrate in the impurity implantation region.

Still preferably, in an alignment mark forming method according to the present invention, in the groove forming step, a depth of the groove is set in consideration of a difference in etching rate between the impurity implantation protecting film and the semiconductor substrate such that a film thickness of greater than or equal to a predetermined film thickness of the impurity implantation protecting film remains on the semiconductor substrate and does not adversely affect a surface of the semiconductor substrate for becoming an active region nor a device characteristic.

Still preferably, in an alignment mark forming method according to the present invention, in the groove forming step, a depth of the groove is set in consideration of a difference in etching rate between the impurity implantation protecting film and the semiconductor substrate such that the impurity implantation protecting film remains on the semiconductor substrate other than the grooves in the alignment mark forming region so as to have a film thickness of greater than or equal to a predetermined film thickness or an exact entirety of the impurity implantation protecting film is removed.

Still preferably, in an alignment mark forming method according to the present invention, in the groove forming step, an etching difference is set in consideration of a difference in etching rate between the impurity implantation protecting film and the semiconductor substrate such that the impurity implantation protecting film remains on the semiconductor substrate other than the grooves in the alignment mark forming region so as to have a film thickness of greater than or equal to a predetermined film thickness or an exact entirety of the impurity implantation protecting film is removed.

Still preferably, in an alignment mark forming method according to the present invention, among a depth and width of the groove and an interval between the grooves, at least the depth of the groove is set such that the one or the plurality of grooves is reflected and appears on a surface of a process layer that is coated and processed in a step subsequent to the groove forming step.

Still preferably, in an alignment mark forming method according to the present invention, in the groove forming step, the depth of the groove is set between 5 nm (including 5 nm) and 150 nm (150 nm).

Still preferably, in an alignment mark forming method according to the present invention, in the groove forming step, the depth of the groove is set between 40 nm (including 40 nm) and 80 nm (80 nm).

Still preferably, in an alignment mark forming method according to the present invention, when the shape of the groove is not reflected and thus does not appear on a surface of a process layer to be coated and processed in a step subsequent to the groove forming step, a portion of the process layer that is located above the groove is removed to expose the groove.

Still preferably, in an alignment mark forming method according to the present invention, in the groove forming step, an etching condition is set such that an etching rate for each of the semiconductor substrate and the impurity implantation protecting film is taken into consideration and also such that a film thickness of the impurity implantation protecting film does not affect a surface of the semiconductor substrate for becoming an active region nor a device characteristic.

Still preferably, in an alignment mark forming method according to the present invention, in the groove forming step, an etching condition is set such that an etching rate for the alignment mark forming pattern, transcribed in the impurity implantation protecting film, with respect to the semiconductor substrate is taken into consideration and also such that a film thickness of the impurity implantation protecting film does not affect a surface of the semiconductor substrate for becoming an active region in the difference portion forming step nor a device characteristic.

Still preferably, in an alignment mark forming method according to the present invention, in the groove forming step, an etching condition is set such that an etching rate for each of the impurity implantation protecting film and the insulating film with respect to the semiconductor substrate is taken into consideration and also such that a film thickness of the impurity implantation protecting film does not affect a surface of the semiconductor substrate for becoming an active region nor a device characteristic.

Still preferably, in an alignment mark forming method according to the present invention, in the groove forming step, an etching condition is set such that an etching rate for the insulating film with respect to the semiconductor substrate is taken into consideration and also such that a film thickness of the impurity implantation protecting film does not affect a surface of the semiconductor substrate for becoming an active region nor a device characteristic.

Still preferably, in an alignment mark forming method according to the present invention, the groove is at least one of a single pole-shaped groove, a plurality of pole-shaped grooves arranged so as to be adjacent to each other, one or a plurality of lattice-shaped grooves and one or a plurality of holes.

An alignment method according to the present invention performs an alignment on at least one of an impurity implantation region and a process layer that are formed after the alignment mark forming step, by using the alignment mark formed by the alignment mark forming method according to the present invention described above, thereby the objective described above being achieved.

A method for manufacturing a semiconductor device according to the present invention include: the step of using the alignment mark formed by the alignment mark forming method according to the present invention described above and using the impurity implantation preventing resist pattern as a mask to form at least one of another impurity implantation region and a process layer, the other impurity implantation region being different from the impurity implantation region with ions of impurity implanted therein, thereby the objective described above being achieved.

A method for manufacturing a solid-state image capturing apparatus according to the present invention includes: a second impurity region forming step of performing an alignment using the alignment mark formed by the alignment mark forming method according to the present invention described above and using the impurity implantation preventing resist pattern formed in the resist film as a mask to form a second impurity region that is different from the first impurity region with the impurity implanted therein; and a third impurity implantation region forming step of performing an alignment using the alignment mark and forming a third impurity region, wherein the first to third impurity implantation regions are formed in a charge transfer region, a channel stop region and a reading gate region, respectively, in an arbitrary order thereof, thereby the objective described above being achieved.

Preferably, a method for manufacturing a solid-state image capturing apparatus according to the present invention further includes: a charge transfer electrode forming step of performing an alignment using the alignment mark and forming a charge transfer electrode as a process film on the first impurity implantation region, the second impurity implantation region and the third impurity implantation region via an insulating film; and a fourth impurity region forming step of performing an alignment using the alignment mark and using the charge transfer electrode as a part of a mask to form a photodiode region.

Still preferably, a method for manufacturing a solid-state image capturing apparatus according to the present invention further includes: subsequent to the fourth impurity region forming step, a light-shielding film forming step of performing an alignment using the alignment mark and covering the charge transfer electrode via the insulating film and forming a light-shielding film having an opening above the photodiode region such that the photodiode region can receive light.

A method for manufacturing a solid-state image capturing apparatus according to the present invention includes: a second impurity region forming step of performing an alignment using the alignment mark formed by the alignment mark forming method according to the present invention described above and using the impurity implantation preventing resist pattern formed in the resist film as a mask to form a second impurity region that is different from a first impurity region with impurity implanted therein; a third impurity implantation region forming step of performing an alignment using the alignment mark and forming a third impurity region; and a fourth impurity region forming step of performing an alignment using the alignment mark and forming a fourth impurity region, wherein the first to fourth impurity implantation regions are formed in a charge transfer region, a channel stop region, a reading gate region and a photodiode region, respectively, in an arbitrary order thereof, thereby the objective described above being achieved.

Preferably, a method for manufacturing a solid-state image capturing apparatus according to the present invention further includes: a charge transfer electrode forming step of performing an alignment using the alignment mark and forming a charge transfer electrode as a process film on the first impurity implantation region, the second impurity implantation region and the third impurity implantation region via an insulating film.

Still preferably, a method for manufacturing a solid-state image capturing apparatus according to the present invention further includes: subsequent to the charge transfer electrode forming step, a light-shielding film forming step of performing an alignment using the alignment mark and covering the charge transfer electrode via the insulating film and forming a light-shielding film having an opening above the photodiode region such that the photodiode region can receive light.

Still preferably, in a method for manufacturing a solid-state image capturing apparatus according to the present invention, in the impurity region forming step, an impurity implantation condition is set such that a film thickness of the impurity implantation protecting film does not affect the semiconductor substrate nor a device characteristic even if a part of the impurity implantation protecting film is removed in the alignment mark forming step and thus becomes thinner or the impurity implantation protecting film is removed in the alignment mark forming step and thus a portion of the impurity implantation protecting film does not exist.

Still preferably, in a method for manufacturing a solid-state image capturing apparatus according to the present invention, the impurity region forming step sets ion species, implantation volume, implantation energy and implantation angle in accordance with a required device characteristic.

Hereinafter, the function of the present invention having the structures described above will be described.

In a conventional semiconductor device and solid-state image capturing apparatus, forming an element separation between impurity implantation regions is conducted as a general technique. However, alignment precision between impurity implantation regions is not the most important factor in determining a device characteristic. Therefore, no particular problem occurred even if the alignment precision between lithography steps in a manufacturing process for a semiconductor device, a solid-state image capturing apparatus and the like was not regarded to require the most stringent alignment precision.

However, as a semiconductor device, a solid-state image capturing apparatus and the like have been recently miniaturized, a pattern size and a pixel size have been further reduced, and thus the margin of error of the device characteristic due to misalignment between steps has been reduced. As such, deterioration in the device characteristic resulting from the alignment deviation between impurity regions and between an impurity implantation region and a process layer (e.g., wiring layer, light-shielding film or the like) formed in a subsequent step has become obvious.

The present invention can use an impurity implantation region as an alignment target layer to reduce a tolerance value in alignment precision between impurity implantation regions in a miniaturized semiconductor device and solid-state image capturing apparatus and also to reduce a tolerance value in alignment precision between an impurity implantation region and a process layer (e.g., wiring layer, light-shielding film or the like) formed in a subsequent step. As a result, it is possible to improve alignment precision.

In order to realize this, when the impurity implantation region is formed, the alignment mark forming resist pattern is exposed to light and formed, at the same time as the impurity implantation preventing resist pattern, in the resist film that is used for forming the impurity implantation preventing resist pattern. The resist film is used as a mask, and the impurity implantation region is formed and at the same time an alignment mark is formed in a semiconductor substrate in consideration of etching selection ratios between each of an oxide film or nitride film and the semiconductor substrate (e.g., silicon).

Hereinafter, further description will be made.

First, in order to avoid an adverse effect on the semiconductor substrate when an impurity implantation is performed, an impurity implantation protecting film made from oxide film or nitride film is formed. Next, a resist pattern is formed using an existing photolithography process only in a region where the formation of an alignment mark is intended. The impurity implantation protecting film in the alignment forming region is removed using an existing dry etching or wet etching. Next, in order to form an impurity implantation region that is intended as an alignment target, an impurity implantation preventing resist pattern having an opening above a region for becoming an impurity implantation region is formed. An alignment mark forming resist pattern having one or a plurality of openings above a region for becoming an alignment mark that is exposed to light at the same time as the formation of the impurity implantation preventing resist pattern is formed in the same resist film.

Further, prior to the impurity implantation step or subsequent to the impurity implantation step, the resist film having the impurity implantation preventing resist pattern and the alignment mark forming resist pattern formed therein is used as a mask to process the alignment mark in the alignment mark forming region of the semiconductor substrate. In this case, an existing etching condition having sufficient etching selection ratios between the impurity implantation protecting film (e.g., oxide film or nitride film) and the semiconductor substrate (e.g., silicon substrate) is used such that an etching does not cause any damage to a semiconductor substrate region where the impurity implantation region for determining the characteristic of a semiconductor device and a solid-state image capturing apparatus is formed. The etching condition is set such that the etching is completed within in the impurity implantation protecting film (or such that the impurity implantation protecting film having greater than or equal to a predetermined film thickness remains) in the impurity implantation region. As such, one or a plurality of grooves for becoming an alignment mark is processed and formed in the alignment mark forming region of the semiconductor substrate.

Alternatively, in order to avoid an adverse effect on the semiconductor substrate when an impurity implantation is performed, an impurity implantation protecting film made from oxide film or nitride film is formed. Thereafter, a resist pattern is formed to form an impurity implantation region that is intended as an alignment target. Simultaneous to this, an alignment mark forming resist pattern is formed in the same resist film. The resist film is used as a mask to etch the impurity implantation protecting film so as to form an alignment mark forming pattern in the impurity implantation protecting film such that an etching does not cause any damage to a semiconductor substrate region where the impurity implantation region for determining the characteristic of a semiconductor device and a solid-state image capturing apparatus is formed. In this case, after the resist film is removed, an alignment mark region forming resist pattern is formed using an existing photolithography process only in a region where the formation of an alignment mark is intended. The resist film having the alignment mark region forming resist pattern formed therein and the impurity implantation protecting film having the alignment mark forming pattern formed therein are used as a mask to process and form one or a plurality of grooves for becoming an alignment mark in the alignment mark forming region of the semiconductor substrate using an existing etching condition.

Alternatively, in the case where an insulating film (e.g., oxide film, nitride film or the like) is formed on the semiconductor substrate for the purpose of element separation, a pattern for becoming an alignment mark can be formed in the insulating film (e.g., oxide film, nitride film or the like) that is formed in the alignment mark forming region, at the same time as the formation of the element separation insulating layer. In this case, in order to avoid an adverse effect on the semiconductor substrate when an impurity implantation is performed, an impurity implantation protecting film made from oxide film or nitride film is formed. Thereafter, an impurity implantation preventing resist pattern is formed to form an impurity implantation region that is intended as an alignment target. Simultaneous to this, an alignment mark forming resist pattern is formed in the same resist film. A resist pattern having an impurity implantation preventing resist pattern and an alignment mark forming resist pattern formed therein is used as a mask to process an alignment mark in the alignment mark forming region of the semiconductor substrate such that an etching does not cause any damage to a semiconductor substrate region where the impurity implantation region for determining the characteristic of a semiconductor device and a solid-state image capturing apparatus is formed. In this case, an existing etching condition having sufficient etching selection ratios between the impurity implantation protecting film (e.g., oxide film or nitride film) and the semiconductor substrate (e.g. , silicon substrate) is used to process and form one or a plurality of grooves f or becoming in alignment mark in the insulating film (e.g., oxide film or nitride film) that is formed in the alignment mark forming region when the element separation insulating film is formed such that an etching does not cause any damage to a semiconductor substrate region where the impurity implantation region for determining the characteristic of a semiconductor device and a solid-state image capturing apparatus is formed. As described above, in the case where an alignment mark is formed in the insulating layer that formed in the alignment mark forming region when the element separation insulating layer is formed, it is possible to have a structure in which no impurity implantation protecting film is provided on the insulating layer.

In this manner, when the impurity implantation region is formed, the alignment mark forming resist pattern is exposed to light and formed, at the same time as the impurity implantation preventing resist pattern, in the resist film that is used for forming the impurity implantation preventing resist pattern. Thus, it is possible to process and form an alignment mark in an insulating film (region where the formation of the alignment mark is intended) that is formed at the same time as a semiconductor substrate and an element separation insulating film. Therefore, it is possible to use the impurity implantation region as an alignment target layer.

In addition, regions (e.g., impurity implantation region) other than the region where the formation of the alignment mark is intended are covered with the impurity implantation protecting film or a separately formed resist film. Thus, no processing is performed on the semiconductor substrate. Further, when an etching condition that does not cause any damage to the semiconductor substrate is selected and used, it is possible to perform an alignment with excellent precision on an impurity implantation region forming layer (impurity implantation region) that is intended as an alignment target layer, without causing any damage to the device characteristic of a semiconductor device, a solid-state image capturing apparatus nor the like, which conventionally occurs.

Further, it is preferable that one or a plurality of grooves for becoming an alignment mark appears on a process layer that is coated and processed in a step subsequent to the alignment mark forming step such that the alignment mark can be accurately recognized by an exposure device in a photolithography step. For this, it is preferable that the depth of the groove for becoming the alignment mark that is formed in the semiconductor substrate in the alignment mark forming step is between 5 nm (including 5 nm) and 150 nm (including 150 nm). Further, it is preferable that the depth of the groove is set in consideration of a case when the groove is directly used as an alignment mark for the semiconductor substrate and a case when a process layer is formed in a subsequent step.

As described above, according to the present invention, in a process of manufacturing a semiconductor device or a solid-state image capturing device, by using the same resist film as a mask to form an impurity implantation region and an alignment mark and using the impurity implantation region as an alignment target layer, it is possible to manage alignment precision between impurity implantation regions and also between an impurity implantation region and a process layer (e.g., wiring layer, light-shielding film or the like) formed in a subsequent step with a highly-precise alignment tolerance value that is equivalent to the value that is required for the most stringent alignment precision in a manufacturing process. Thus, it is possible to accommodate a miniaturized semiconductor device and solid-state image capturing apparatus.

In addition, since one or a plurality of grooves formed in a semiconductor substrate or an element separation insulating layer can be used as an alignment mark, it is possible to perform an alignment by various alignment methods, such as an alignment method for detecting the position of the alignment mark using scattered light from a difference portion as a detection signal waveform with respect to incident light from a light source for alignment, and an alignment method for detecting the position of the alignment mark using, as a detection signal waveform, light/dark observed at an edge portion of a difference using an image viewed from above the alignment mark portion.

Further, since only the alignment mark forming region has the openings, and portions other than the alignment mark forming region are covered with an impurity protecting film or a resist film, no groove is processed in a semiconductor substrate region in an active region where the processing of groove is not intended, or an etching condition can be selected such that it does not cause any damage to the semiconductor substrate and process the semiconductor substrate. As such, a required characteristic of semiconductor device or solid-state image capturing apparatus can be obtained.

These and other advantages of the present invention will become apparent to those skilled in the art upon reading and understanding the following detailed description with reference to the accompanying figures.

### BRIEF DESCRIPTION OF THE DRAWINGS

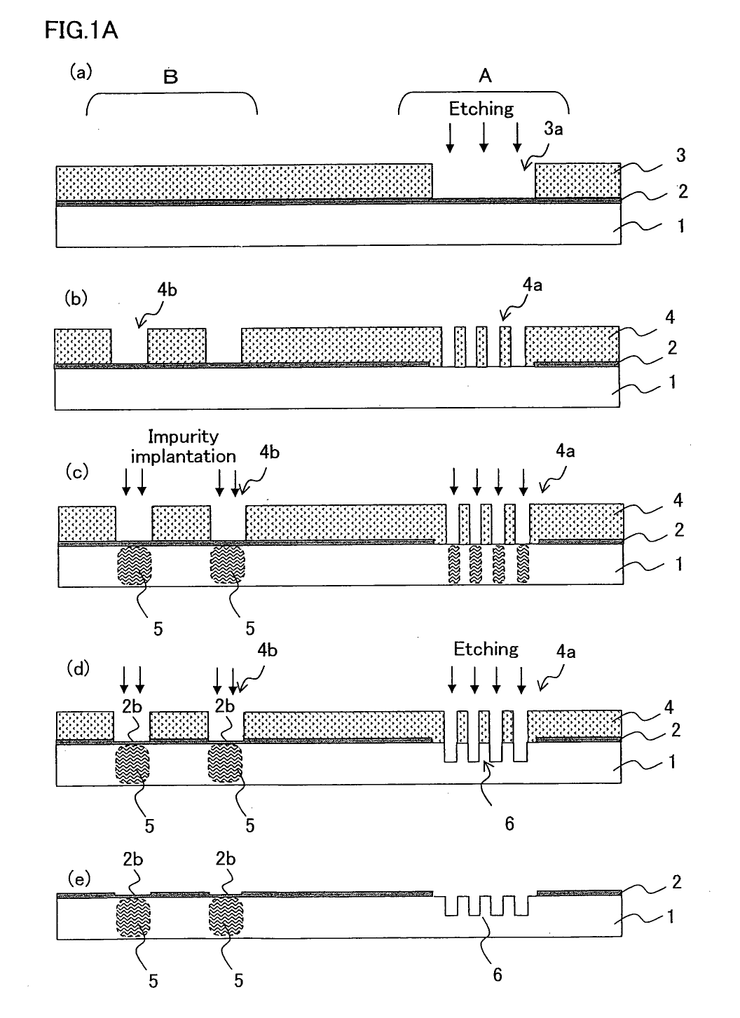

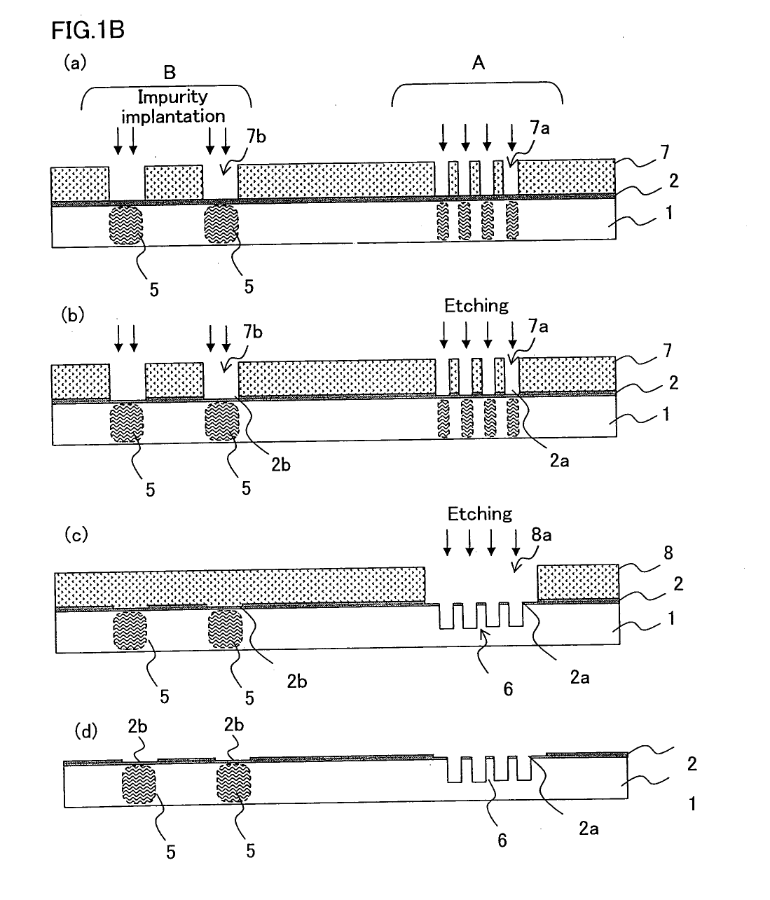

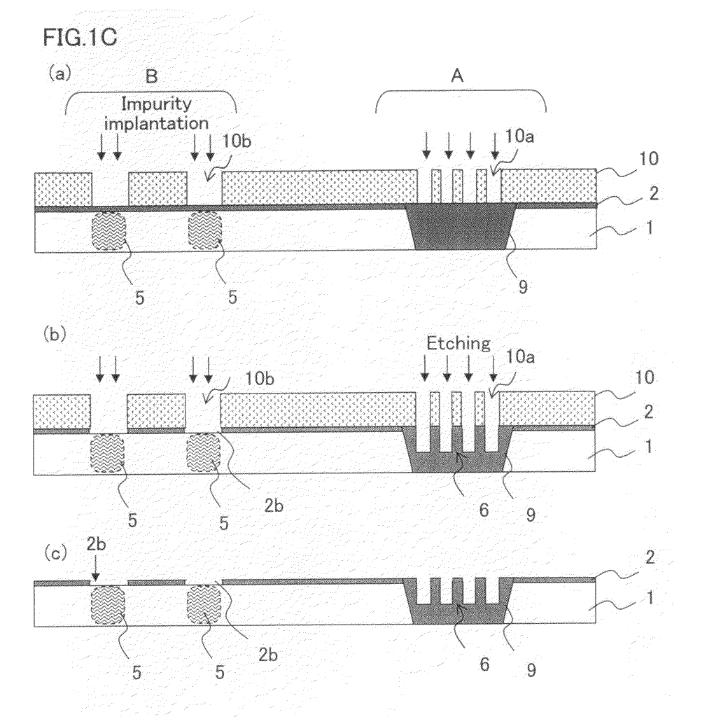

Portions (a) to (e) of FIG. 1A is a longitudinal cross-sectional view showing an essential part in steps of manufacturing of a semiconductor device for describing an alignment mark forming method according to Embodiment 1 of the present invention.

Portions (a) to (d) of FIG. 1B is a longitudinal cross-sectional view showing an essential part in steps of manufacturing of a semiconductor device for describing an alignment mark forming method according to Embodiment 2 of the present invention.

Portions (a) to (c) of FIG. 1C is a longitudinal cross-sectional view showing an essential part in steps of manufacturing of a semiconductor device for describing an alignment mark forming method according to Embodiment 3 of the present invention.

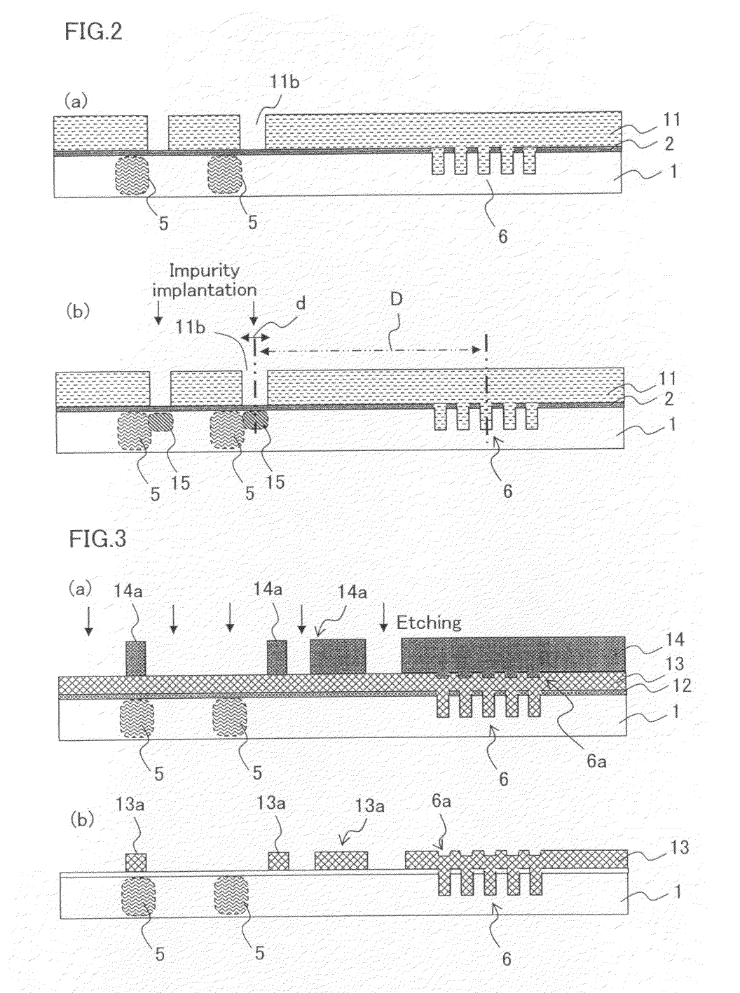

Portions (a) and (b) of FIG. 2 are each a view for describing an alignment method according to Embodiment 4 of the present invention and are each a longitudinal cross-sectional view showing an essential part in a step of manufacturing a semiconductor device for describing alignment precision in a case in which an alignment for another impurity implantation region is performed using the alignment mark that is formed in the alignment mark forming step shown in Portion (d) of FIG. 1A.

Portions (a) and (b) of FIG. 3 are each a view for describing an alignment method according to Embodiment 5 of the present invention and are each a longitudinal cross-sectional view showing an essential part in a step of manufacturing a semiconductor device for describing alignment precision in a case in which an alignment between the impurity implantation region and a wiring layer formed in a subsequent step is performed using the alignment mark that is formed in the alignment mark forming step shown in Portion (d) of FIG. 1A.

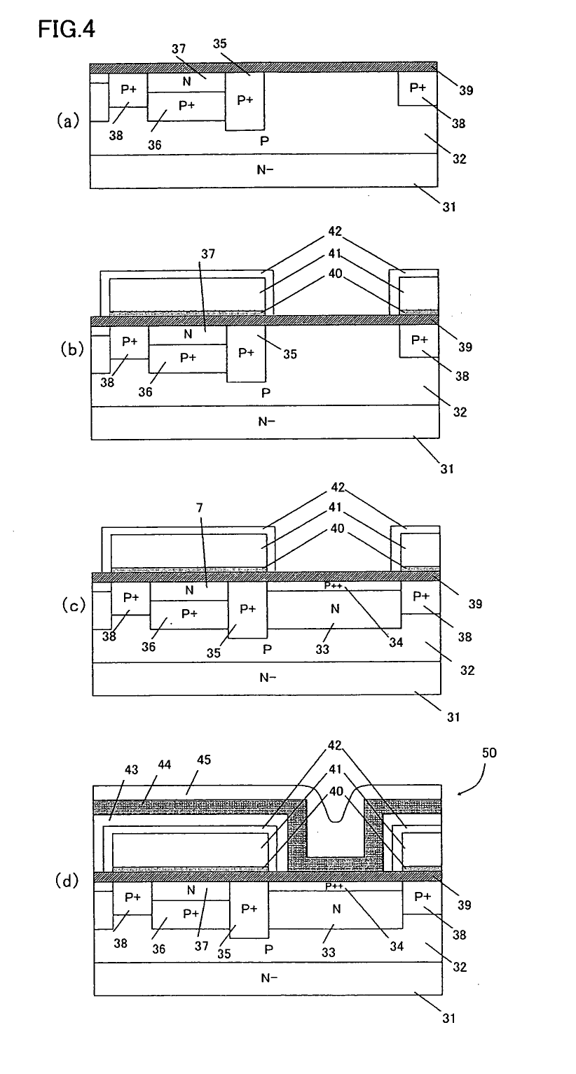

Portions (a) to (d) of FIG. 4 are each a longitudinal cross-sectional view showing a substrate portion for describing a step of manufacturing a solid-state image capturing apparatus according to Embodiment 6 of the present invention.

Portions (a) to (c) of FIG. 5 are each a longitudinal cross-sectional view showing a step of manufacturing a conventional semiconductor device for describing a conventional alignment mark forming method.

A alignment mark forming region

B active region

D distance between the alignment mark 6 and the impurity implantation region 15

d misalignment tolerance range for the impurity implantation region 15

1 semiconductor substrate

2 impurity implantation protecting film

2a alignment mark forming pattern transcribed in the impurity implantation protecting film

2b impurity implantation preventing pattern transcribed in the impurity implantation protecting film (difference portion)

3 photo-resist film

3a alignment mark region forming photo-resist pattern (opening)

4 photo-resist film

4a alignment mark forming photo-resist pattern

4b impurity implantation preventing photo-resist pattern

5 impurity implantation region (alignment target layer)

6 alignment mark (portion processed in the substrate; groove)

7 photo-resist film

7a alignment mark forming photo-resist pattern

7b impurity implantation preventing photo-resist pattern

8 photo-resist film

8a alignment mark region forming photo-resist pattern

9 element separation insulating layer

10 photo-resist film

10a alignment mark forming photo-resist pattern

10b impurity implantation preventing photo-resist pattern

11 photo-resist film

11b impurity implantation preventing photo-resist pattern

12 oxide film

13 wiring film

13b wiring layer

14 photo-resist film

14a wiring layer processing photo-resist pattern

15 another impurity implantation region

31 N-type silicon substrate

32 P-type semiconductor well region

33 N-type impurity diffusion region

34 high-concentration P-type impurity diffusion region

35 P-type semiconductor region

36 P-type semiconductor active region

37 N-type semiconductor active region

38 channel stop region (P-type impurity diffusion region)

39 SiO₂ film

40 Si₃N₄ film

41 charge transfer electrode

42 inter-layer insulating film

43 light-shielding film

44 inter-layer insulating film

45 BPSG film

50 CCD solid-state image capturing apparatus (semiconductor device)

D1 distance between the alignment mark 102 and the impurity implantation region 104

D2 distance between the alignment mark 102 and the impurity implantation region 106

d1 misalignment tolerance range for the impurity implantation region 104

d2 misalignment tolerance range for the impurity implantation region 106

101 semiconductor substrate

102 alignment mark (conventional)

103 impurity implantation protecting film

104 impurity implantation region

105 photo-resist film

105a impurity implantation preventing photo-resist pattern

106 another impurity implantation region

107 photo-resist film

107a another impurity implantation preventing photo-resist pattern

### DESCRIPTION OF THE PREFERRED EMBODIMENTS

Hereinafter, Embodiments 1 to 3 in which an alignment mark forming method according to the present invention is applied to a semiconductor device manufacturing method, Embodiments 4 and 5 in which an alignment method according to the present invention is applied to the semiconductor device manufacturing method, and Embodiment 6 in which the alignment mark forming method according to the present invention and the alignment method according to the present invention are applied to a solid-state image capturing apparatus manufacturing method will be described in detail with reference to the accompanying drawings. It should bed noted that the solid-state image capturing apparatus includes, in addition to a CCD (couple-charged device) solid-state image capturing device, a CMOS (complementary MOS) solid-state image capturing apparatus for amplifying signal charge for each pixel and obtaining an image capturing signal.

### Embodiment 1

Embodiment 1 will describe a case in which in an alignment mark forming step subsequent (or prior) to an impurity implantation region forming step, the same photo-resist film is used as a mask both at the impurity implantation region forming step and the alignment mark forming step, and an etching difference is formed in an impurity implantation protecting film above an impurity implantation region in an active region B, and a predetermined groove is formed in an alignment mark forming region A.

FIG. 1A is a longitudinal cross-sectional view showing an essential part in steps of manufacturing of a semiconductor device for describing an alignment mark forming method according to Embodiment 1 of the present invention.

As shown in Portion (a) of FIG. 1A, an impurity implantation protecting film 2 is coated on the semiconductor substrate 1. A pattern in a photo-resist film 3 is formed such that an opening 3a is located in the alignment mark forming region A and also such that a region for becoming the active region B is covered. Then, the impurity implantation protecting film 2 below the opening 3a is removed.

In this case, the film thickness of the impurity implantation protecting film 2 is set in consideration that an etching process be completed within the impurity implantation protecting film 2 above an impurity implantation region forming layer (impurity implantation region) 5 such that the thickness of the impurity implantation protecting film 2 does not affect the semiconductor substrate 1 in an impurity ion implantation step that uses the impurity implantation region 5 to be described later as an alignment target layer even if the impurity implantation protecting film 2 is removed and thus becomes thinner by the etching process in an alignment mark forming step to be described later and also such that the thickness of the impurity implantation protecting film 2 does not affect the impurity implantation region 5 in a step of forming an alignment mark in the semiconductor substrate 1 that is performed by a known etching technique using, as a mask, an alignment mark forming photo-resist pattern 4a resolved at the same time as an impurity implantation preventing photo-resist pattern 4b to be described later. For example, as the impurity implantation protecting film 2, an oxide film or a nitride film is coated by a known coating technique such that the film thickness thereof is between 50 Å (including 50 Å) and 2000 Å (including 2000 Å).

In addition, in order to resolve the pattern in the opening 3a of the photo-resist film 3, an application step and a development step of photo-resist material are performed, in view of known conditions that match a light source and other materials, using a known technique of reduced projection exposure apparatus (i.e., stepper) that has an exposure light source selected in consideration of a required resolution performance among exposure light sources such as i laser (wavelength of 365 nm), KrF exima laser (wavelength of 248 nm), ArF exima laser (wavelength of 193 nm) and the like, and an application step of reflection preventing film can be performed, as necessary. Further, a conventionally-used alignment mechanism can be used for an alignment mechanism in the stepper. It should be noted that as a technique for resolving a photo-resist pattern as in the case described above, the conventionally-used lithography technique is used in a subsequent step unless a specific description is made thereabout, and a required photo-resist pattern is resolved.

Further, selective removal of apart or the entirety of the impurity implantation protecting film 2 is performed by a wet etching technique for processing/cleansing with a known concentration, liquid immersion time and the like using etching liquid (e.g., hydrofluoric acid that is used for the oxide film, phosphoric acid that is used for the nitride film or the like) or a dry etching technique that is controlled by known vacuum degree, gas mixing ratio, gas flow volume, plasma-applied voltage and the like such that a sufficient difference in etching rate for the semiconductor substrate 1 (e.g., silicon substrate) is obtained with respect to the oxide film or the nitride film that is used as the impurity implantation protecting film 2. Similar thereto, films such as oxide film, nitride film, silicon substrate and the like will be processed by a known etching technique that holds a required etching rate in a subsequent step unless a specific description is made thereabout. In this case, the film thickness of the impurity protecting film 2 to be removed is between 10% (including 10%) and 100% (including 100%) of the entire film thickness of the impurity implantation protecting film 2.

It should be noted that a required film thickness of the photo-resist film 3 is held such that a portion below the photo-resist film 3 is protected at the time of etching for selectively removing the entire impurity implantation protecting film 2 in the opening 3a that corresponds to the alignment mark forming region A.

Next, as shown in Portion (b) of FIG. 1A, an impurity implantation preventing photo-resist pattern 4b having an opening above a region for becoming the impurity implantation region 5 to be described later is designed to be formed in the active region B, and at the same time a pattern for processing an alignment mark in the same photo-resist layer is designed to be formed in order to use the impurity implantation region 5 as an alignment target layer. The photo-resist film 4 having a resolved alignment mark forming photo-resist pattern 4a that has one or a plurality of openings above a region for becoming the alignment mark 6 is formed in the alignment mark forming region A. A required film thickness of the photo-resist film 4 is held for a portion where an implantation of impurity is not intended, in order to prevent the implantation of impurity therein.

Thereafter, in an ion implantation step (impurity implantation region forming step) shown in Portion (c) of FIG. 1A, in order to form the impurity implantation region 5 in the semiconductor substrate 1, the impurity implantation preventing photo-resist pattern 4b is used as a mask, and impurity ions are implanted in the semiconductor substrate 1 through the opening (pattern) of the impurity implantation preventing photo-resist pattern 4b. Boron (B) ion, phosphorus (P) ion, arsenic (As) ion and the like are typical of impurity ion species to be used. Ion species, implantation volume, implantation energy and implantation angle are taken into consideration in each impurity implantation region forming step in order to determine a device characteristic. With those considered ion species, implantation volume, implantation energy and implantation angle, the impurity ions is implanted in a predetermined region of the semiconductor substrate 1. Thus, the impurity implantation region 5 is formed at a predetermined location of the semiconductor substrate 1. Simultaneous thereto, the alignment mark forming photo-resist pattern 4a is used as a mask, and impurity ions are implanted in a predetermined region of the semiconductor substrate 1 through one or a plurality of openings (pattern) of the alignment mark forming photo-resist pattern 4a.

Further, as shown in Portion (d) of FIG. 1A, the alignment mark forming photo-resist pattern 4a that is formed in a portion where the impurity implantation protecting film 2 is removed in the alignment mark forming region A is used as a mask, and a dry etching is performed on the alignment mark forming region A of the semiconductor substrate 1 to form one or a plurality of grooves for becoming an alignment mark 6. The etching condition therefor is set such that the etching rate for each of the semiconductor substrate 1 and the impurity implantation protecting film 2 is taken into consideration and also such that the thickness of the impurity implantation protecting film 2 does not affect the surface of the semiconductor substrate 1 for becoming the active region B nor the device characteristic. In this case, due to the dry etching of the alignment mark forming region A of the semiconductor substrate 1 (e.g., silicon substrate), the active region B and the impurity implantation region 5 are covered with the impurity implantation protecting film 2 that is coated to have a film thickness that is set in consideration of an etching rate for the oxide film or nitride film formed as the impurity implantation protecting film 2 and also in consideration of a natural oxide film to be removed such that the film thickness of the impurity implantation protecting film 2 is not affected by the dry etching. The natural oxide film is coated to so as to have a film thickness of about 2 nm on the semiconductor substrate 1 that is exposed to the atmosphere after the impurity implantation protecting film 2 is removed in Portion (a) of FIG. 1A. The dry etching is completed within the impurity implantation protecting film 2, and thus an etching difference 2b is formed in the impurity implantation protecting film 2. However, in this case, a substrate portion that is below the etching difference 2b and that is above the impurity implantation region 5 of the active region B is not etched owing to the impurity implantation protecting film 2.

The depth and width of a groove and the interval between grooves for becoming the alignment mark 6 to be processed in the semiconductor substrate 1 are set in consideration of a case when the alignment mark 6 is directly used as an alignment mark for the semiconductor substrate 1 and a case when the grooves of the alignment mark 6 are used as an alignment mark such that predetermined grooves appear on a process layer that is coated and processed in a subsequent step. For example, the depth of the grooves for becoming the alignment mark 6 is set between 5 nm (including 5 nm) and 150 nm (including 150 nm). More preferably, the depth of the grooves for becoming the alignment mark 6 is set between 40 nm (including 40 nm) and 80 nm (including 80 nm). When the depth of the grooves exceeds 150 nm, unevenness in a photo-resist application is likely to occur due to the difference of the groove. 5 nm of the depth of the groove is a limit value in order to detect a groove for alignment.

When the shape of the groove for becoming the alignment mark 6 is not reflected and thus does not appear on a process layer to be coated and processed in a step subsequent to the alignment mark forming step, a portion of the process layer that is located above the groove can be removed to expose the groove.

Thereafter, as shown Portion (e) of FIG. 1A, the photo-resist film 4 is removed from the semiconductor substrate 1 (or impurity implantation protecting film 2) by 02 plasma, sulfuric acid or the like. In a step subsequent thereto, process layers, such as impurity implantation region, wiring layer and light-shielding film, are formed.

As described above, Embodiment 1 has described an alignment mark forming method for forming the difference portion 2b and the alignment mark 6 that are used when a patterning is performed in at least one of a subsequent impurity implantation step and a subsequent process layer forming step, using the impurity implantation region 5 as an alignment target layer. The alignment mark forming method includes: a protecting film coating step of coating the impurity implantation protecting film 2 on the semiconductor substrate 1; a protecting film removing step of removing the impurity implantation protecting film 2 in the alignment mark forming region A; a resist pattern forming step of coating a resist film on the semiconductor substrate 1, and forming the impurity implantation preventing resist pattern 4b having an opening above a region for becoming the impurity implantation region 5 and forming the alignment mark forming resist pattern 4a having one or a plurality of openings above a region for becoming the alignment mark 6; and subsequent to the impurity implantation step (or prior to the impurity implantation step), a groove and difference forming step of using, as a mask, the resist film 4 having the impurity implantation preventing resist pattern 4b and the alignment mark forming resist pattern 4a therein to form one or a plurality of grooves as an alignment mark in the alignment mark forming region A of the semiconductor substrate 1 where the impurity implantation protecting film 2 is removed, and forming a difference portion 2b in the impurity implantation protecting film 2 that corresponds to the impurity implantation preventing resist pattern 4b.

As described above, when the impurity implantation region 5 is formed, the alignment mark forming resist pattern 4a is formed, at the same time as the impurity implantation preventing resist pattern 4b, in the resist film 4 that is used for forming the impurity implantation preventing resist pattern 4b. The entire impurity implantation protecting film 2 in the alignment mark forming region A (entire impurity implantation protecting film 2 in the film thickness direction thereof) is selectively removed in advance. Subsequent to (or prior to) the impurity implantation step, the photo-resist film 4 is used as a mask, and predetermined one or a plurality of grooves for becoming the alignment mark 6 is formed in the one or a plurality of openings of the semiconductor substrate 1 where the impurity implantation protecting film 2 is removed. In this case, the same photo-resist film 4 is used as a mask both in the impurity implantation region forming step and the alignment mark forming step, and the etching difference 2b is formed at a location of the impurity implantation protecting film 2 that corresponds to the impurity implantation region 5. As such, the impurity implantation region can be used as an alignment target layer. Thus, the alignment precision can be improved, and this can accommodate a miniaturized semiconductor device and solid-state image capturing apparatus.

A part of the etching difference (difference portion 2b) processed when the alignment mark 6 is formed is present in the impurity implantation protecting film 2 of the active region B. However, when the impurity implantation step is continuously preformed, a film thickness of the impurity implantation protecting film 2 and an impurity implantation condition are set such that the impurity implantation protecting film 2 as an implantation protecting film having a film thickness minus the etching difference (difference portion 2b) does not affect the semiconductor substrate 1 in the active region B nor the device characteristic. More preferably, the entire impurity implantation protecting film 2 is removed from the semiconductor substrate 1, and a film having a film thickness considered as an impurity implantation protecting film is newly coated in a subsequent step.

Further, even with the impurity implantation protecting film 2 having the film thickness minus the etching difference (difference portion 2b), in the case where the film thickness of the impurity implantation protecting film 2 is set such that the film thickness of the impurity implantation protecting film 2 does not affect the semiconductor substrate 1 in the active region B nor the device characteristic and also such that the shape of the alignment mark forming resist pattern 4a and the film thickness of the resist film 4 after the etching process do not affect the formation of the impurity forming region 5, impurity can be implanted after the etching process.

### Embodiment 2

Embodiment 2 will describe a case in which an etching difference (difference portion 2a) corresponding to the alignment mark forming region A is formed in addition to the formation of the etching difference (difference portion 2b) corresponding to the active region B, the etching difference (difference portion 2a) is used as a mask to form a plurality of grooves for becoming the alignment mark 6 in the semiconductor substrate 1.

FIG. 1B is a longitudinal cross-sectional view showing an essential part in steps of manufacturing of a semiconductor device for describing an alignment mark forming method according to Embodiment 2 of the present invention.

First, as shown in Portion (a) of FIG. 1B, the impurity implantation protecting film 2 made from oxide film, nitride film or the like is coated on the semiconductor substrate 1.

An impurity implantation preventing photo-resist pattern 7b having an opening above a region for becoming the impurity implantation region 5 to be described later is designed to be formed on the active region B, and at the same time a pattern for processing an alignment mark in the same photo-resist layer is designed to be formed in order to use the impurity implantation region as an alignment target layer. The photo-resist film 7 having a resolved alignment mark forming photo-resist pattern 7a that has one or a plurality of openings above a region for becoming the alignment mark 6 is formed in the alignment mark forming region A. A required film thickness of the photo-resist film 7 is held for a portion where an implantation of impurity is not intended, in order to prevent the implantation of impurity therein. In addition, the impurity implantation protecting film 2 is formed such that the film thickness thereof is between 50 Å (including 50 Å) and 2000 Å (including 2000 Å), for example. In this case, the film thickness of 50 Å is the minimum film thickness that is required in order to protect the surface of the semiconductor substrate 1 from becoming rough when impurity is implanted. When the film thickness of the impurity implantation protecting film 2 is greater than or equal to 2000 Å, this requires time to remove the impurity implantation protecting film 2 in a subsequent step.

Next, in order to form the impurity implantation region 5 in the semiconductor substrate 1 in an ion implantation step (impurity implantation region forming step), the impurity implantation preventing photo-resist pattern 7b is used as a mask, and impurity ions are implanted in the semiconductor substrate 1 through an opening (pattern) of the impurity implantation preventing photo-resist pattern 7b. For the implantation condition in this case, ion species, implantation volume, implantation energy and implantation angle are taken into consideration in each impurity implantation region forming step in order to determine a device characteristic.

Next, as shown in Portion (b) of FIG. 1B, the photo-resist film 7 is used as a mask to selectively etch and remove a part of the impurity implantation protecting film 2 located at the opening in the photo-resist film 7. In this case, difference in etching rate between the impurity implantation protecting film 2 and the semiconductor substrate 1 (e.g., silicon substrate) is taken into consideration in order to form the alignment mark 6 to be described later in the semiconductor substrate 1. With this consideration, the impurity implantation protecting film 2 is etched up to a depth such that the thickness of the impurity implantation protecting film 2 does not affect the semiconductor substrate 1 in the active region B nor the device characteristic. As such, the alignment mark forming pattern 7a is transcribed in the impurity implantation protecting film 2. In addition, an etching condition having a sufficient difference in etching rate between the silicon substrate (semiconductor substrate 1) and the oxide film or the nitride film (the impurity implantation protecting film 2) is set such that the thickness of the impurity implantation protecting film 2 does not affect the surface of the active region B of the semiconductor substrate 1 nor the device characteristic. As such, the entire impurity implantation protecting film 2 at the opening of the impurity implantation preventing photo-resist pattern 7b can be removed. The film thickness of the impurity implantation protecting film 2 to be removed is set between 10% (including 10%) and 100% (including 100%) of the entire film thickness of the impurity implantation protecting film 2, for example.

Next, as shown Portion (c) of FIG. 1B, the photo-resist film 7 is removed from the semiconductor substrate 1 (or impurity implantation protecting film 2) by 02 plasma, sulfuric acid or the like. A pattern in the photo-resist film 8 is formed on the impurity implantation protecting film 2 such that an opening 8a is located in the alignment mark forming region A.

In this case, by exposing to light and developing the alignment mark forming region A and by patterning the photo-resist film 8 so as to have a predetermined opening shape, the resist film 7 having the resolved alignment mark forming pattern 7a is used as a mask to expose the alignment mark forming pattern 2a formed in the impurity implantation protecting film 2.

Thus, portions other than the alignment mark forming region A are protected, by the pattern in the photo-resist film 8, from the etching process that is performed when the alignment mark is formed. The alignment mark forming pattern (difference portion 2a) transcribed in the impurity implantation protecting film 2 and the pattern in the photo-resist film 8 are used as a mask, and the etching process is performed on the semiconductor substrate 1 to form one or a plurality of grooves for becoming the alignment mark 6.

In this case, the etching process is performed with a known etching technique, and the etching condition therefore is set such that difference in etching rate for the alignment mark forming pattern 2a, transcribed in the impurity implantation protecting film 2, with respect to the silicon substrate (e.g., semiconductor substrate 1) is taken into consideration and also such that the thickness of the impurity implantation protecting film 2 does not affect the surface of the semiconductor substrate 1 corresponding to the active region B nor the device characteristic.

The depth and width of a groove and the interval between grooves for becoming the alignment mark 6 to be processed in the semiconductor substrate 1 are set in consideration of a case when the alignment mark 6 is directly used as an alignment mark for the semiconductor substrate 1 and a case when the grooves of the alignment mark 6 are used as an alignment mark such that predetermined grooves appear on a process layer that is coated and processed in a subsequent step. For example, the depth of the grooves for becoming the alignment mark 6 is set between 5 nm (including 5 nm) and 150 nm (including 150 nm). More preferably, the depth of the grooves for becoming the alignment mark 6 is set between 40 nm (including 40 nm) and 80 nm (including 80 nm). When the depth of the grooves exceeds 150 nm, unevenness in a photo-resist application is likely to occur due to the difference of the groove. When the shape of the groove for becoming the alignment mark 6 is not reflected and thus does not appear on a process layer to be coated and processed in a step subsequent to the alignment mark forming step, a portion of the process layer that is located above the groove can be removed to expose the groove.

Thereafter, as shown Portion (d) of FIG. 1B, the photo-resist film 8 is removed from the semiconductor substrate 1 (or impurity implantation protecting film 2) by O₂ plasma, sulfuric acid or the like. In a step subsequent thereto, process layers, such as impurity implantation region, wiring layer and light-shielding film, are formed.

As described above, Embodiment 2 has described an alignment mark forming method for forming the difference portion 2b and the alignment mark 6 that are used when a patterning is performed in at least one of a subsequent impurity implantation step and a subsequent process layer forming step, using the impurity implantation region 5 as an alignment target layer. The alignment mark forming method includes: a protecting film coating step of coating the impurity implantation protecting film 2 on the semiconductor substrate 1; a first resist pattern forming step of coating a photo-resist film on the impurity implantation protecting film 2, and forming the impurity implantation preventing resist pattern 7b having an opening above a region for becoming the impurity implantation region 5 in the photo-resist film and at the same time exposing and forming the alignment mark forming resist pattern 7a having one or a plurality of openings (pattern) above a region for becoming the alignment mark 6; subsequent to the impurity implantation step (or prior to the impurity implantation step), a difference portion forming step of using, as a mask, the photo-resist film 7 formed by exposing the impurity implantation preventing resist pattern 7b and the alignment mark forming resist pattern 7a at the same time to selectively remove a part or the entirety of the impurity implantation protecting film 2 that corresponds to the opening of the photo-resist film 7 so as to form the difference portions 2a, 2b in the impurity implantation protecting film 2; a resist film removing step of removing the photo-resist film 7; a second resist pattern forming step of newly coating another photo-resist film on the semiconductor substrate 1 and forming the alignment mark region forming resist pattern 8a having an opening above a region for becoming the alignment mark 6 in the other photo-resist film; and a groove forming step of using, as a mask, the resist film 8 having the alignment mark region forming resist pattern 8a formed therein and the impurity implantation protecting film having the alignment mark forming pattern 2a formed therein and forming one or a plurality of grooves for becoming the alignment mark 6 in the alignment mark forming region A of the semiconductor substrate 1.

As described above, when the impurity implantation region 5 is formed, the alignment mark forming resist pattern 7a is exposed to light and formed, at the same time as the impurity implantation preventing resist pattern 7b, in the resist film 7 that is used for forming the impurity implantation preventing resist pattern 7b. An alignment mark forming pattern that corresponds to the alignment mark forming resist pattern 7a is transcribed in the impurity implantation protecting film 2 to form the difference portion 2a, and an impurity implantation preventing pattern that corresponds to the impurity implantation preventing resist pattern 7b is transcribed in the impurity implantation protecting film 2 to form the difference portion 2b. The photo-resist film 8 having an opening of the alignment mark forming region A is formed on the impurity implantation protecting film 2, and the etching difference (difference portion 2a) in the impurity implantation protecting film 2 is used as a mask to form a plurality of grooves for becoming the alignment mark 6 in the semiconductor substrate 1. As such, the impurity implantation region 5 can be used as an alignment target layer. Thus, the alignment precision can be improved, and this can accommodate a miniaturized semiconductor device and solid-state image capturing apparatus.

A part of the etching difference (difference portion 2b) processed when the alignment mark 6 is formed is present in the impurity implantation protecting film 2 in the active region B after the processing. However, when the impurity implantation step is continuously preformed, an impurity implantation condition is set such that the thickness of the impurity implantation protecting film 2 does not affect the semiconductor substrate 1 in the active region B nor the device characteristic even if the etching difference (difference portion 2b) is absent in the impurity implantation protecting film 2. Alternatively, a pattern layout can be designed such that the portion corresponding to the etching difference (difference portion 2b) is covered with the implantation impurity preventing photo-resist film 7 when the impurity implantation protecting film 2 is absent. More preferably, the entire impurity implantation protecting film 2 is removed from the semiconductor substrate 1, and a film having a film thickness considered as an impurity implantation protecting film is newly coated in a subsequent step.

In addition, even if the impurity implantation protecting film 2 is absent in the etching difference (difference portion 2b), an impurity implantation can be performed after the etching process in the case where an impurity implantation condition is set such that the thickness of the impurity implantation protecting film 2 does not affect the semiconductor substrate 1 in the active region B nor the characteristic device and also in the case where the patterning shape of the alignment mark forming resist pattern 7a and the film thickness of the resist film after the etching process do not affect the formation of the impurity implantation region 5.

### Embodiment 3

Embodiment 3 will describe a case in which the same photo-resist film is used as a mask, after or before the impurity implantation, for an alignment mark region insulating layer that is formed in the alignment mark forming region A at the same time as an element insulating film in order to form a difference portion in the impurity implantation protecting film of the active region B and also in order to form one or a plurality of grooves for becoming an alignment mark in the alignment mark region insulating layer.

FIG. 1C is a longitudinal cross-sectional view showing an essential part in steps of manufacturing of a semiconductor device for describing an alignment mark forming method according to Embodiment 3 of the present invention.

First, as shown in Portion (a) of FIG. 1C, in an insulating film forming step of forming an insulating film (e.g., oxide film, nitride film or the like) on the semiconductor substrate 1 for the purpose of element separation, an alignment mark region insulating layer 9 having the same structure as the insulating film (e.g., oxide film, nitride film or the like) is formed for the alignment mark forming region A.

Next, the impurity implantation protecting film 2 is coated on the semiconductor substrate 1 and the alignment mark region insulating layer 9. An impurity implantation preventing photo-resist pattern 10B having an opening above a region for becoming the impurity implantation region 5 to be described later is designed to be formed in the active region B, and at the same time a pattern for processing an alignment mark in the same photo-resist layer is designed to be formed in order to use the impurity implantation region 5 as an alignment target layer. The photo-resist film 10 having a resolved alignment mark forming photo-resist pattern 10a that has one or a plurality of openings above a region for becoming the alignment mark 6 is formed in the alignment mark region insulating layer 9 in the alignment mark forming region A. A required film thickness of the photo-resist film 10 is held for a portion where an implantation of impurity is not intended, in order to prevent the implantation of impurity therein. In addition, the impurity implantation protecting film 2 is formed such that the film thickness thereof is between 50 Å (including 50 Å) and 2000 Å (including 2000 Å), for example.

Further, in order to form the impurity implantation region 5 in the semiconductor substrate 1 in an ion implantation step (impurity implantation region forming step), the impurity implantation preventing photo-resist pattern 10b is used as a mask, and impurity ions are implanted in the semiconductor substrate 1 through an opening (pattern) of the impurity implantation preventing photo-resist pattern 10b. For the implantation condition in this case, ion species, implantation volume, implantation energy and implantation angle are taken into consideration in each impurity implantation region forming step in order to determine a device characteristic.

Next, as shown in Portion (b) of FIG. 1C, the photo-resist film 10 is used as a mask, and the alignment mark region insulating layer 9 is processed so as to form one or a plurality of grooves for becoming the alignment mark 6 in the alignment mark region insulating layer 9. The impurity implantation protecting film 2 above the impurity implantation region 5 has an etching difference (difference portion 2b) since the impurity implantation protecting film 2 of the entire film thickness above the impurity implantation region 5 is selectively removed by an etching process.

In this case, the etching process is performed with a known etching technique, and the etching condition therefore is set such that difference in etching rate for each of the alignment mark forming pattern 2a and the oxide film or nitride film (alignment mark region insulating layer 9) with respect to the silicon substrate (semiconductor substrate 1) is taken into consideration and also such that the thickness of the impurity implantation protecting film 2 does not affect the surface of the semiconductor substrate 1 in the active region B nor the device characteristic even if the entire film thickness of the impurity implantation protecting film 2 below the opening (impurity implantation preventing photo-resist pattern 10b) of the resist film 10 is removed.

The depth and width of a groove and the interval between grooves for becoming the alignment mark 6 to be processed in the semiconductor substrate 1 are set in consideration of a case when the alignment mark 6 is directly used as an alignment mark for the semiconductor substrate 1 and a case when the grooves of the alignment mark 6 are used as an alignment mark such that predetermined grooves appear on a process layer that is coated and processed in a subsequent step. For example, the depth of the grooves for becoming the alignment mark 6 is set between 5 nm (including 5 nm) and 150 nm (including 150 nm). More preferably, the depth of the grooves for becoming the alignment mark 6 is set between 40 nm (including 40 nm) and 80 nm (including 80 nm). When the depth of the grooves exceeds 150 nm, unevenness in a photo-resist application is likely to occur due to the difference of the groove. When the shape of the groove for becoming the alignment mark 6 is not reflected and thus does not appear on a process layer to be coated and processed in a step subsequent to the alignment mark forming step, a portion of the process layer that is located above the groove can be removed to expose the groove.

Thereafter, as shown Portion (c) of FIG. 1C, the photo-resist film 10 is removed from the semiconductor substrate 1 (or impurity implantation protecting film 2) by O₂ plasma, sulfuric acid or the like. In a step subsequent thereto, process layers, such as impurity implantation region, wiring layer and light-shielding film, are formed.

As described above, Embodiment 3 has described an alignment mark forming method for forming the difference portion 2b and the alignment mark 6 that are used when a patterning is performed in at least one of a subsequent impurity implantation step and a subsequent process layer forming step, using the impurity implantation region 5 as an alignment target layer. The alignment mark forming method includes: an insulating film forming step of forming an insulating layer in the semiconductor substrate 1 for the purpose of separating elements; a protecting film coating step of coating the impurity implantation protecting film 2 on the semiconductor substrate 1 and the insulating layer; a resist pattern forming step of coating a resist film on the impurity implantation protecting film 2, and forming the impurity implantation preventing resist pattern 10b having an opening above the active region B for becoming the impurity implantation region 5 and forming the alignment mark forming resist pattern 10a having one or a plurality of openings above a region for becoming the alignment mark 6 in the alignment mark region insulating layer 9 that is formed in the alignment mark forming region A in the insulating layer forming step; and subsequent to the impurity implantation step or prior to the impurity implantation step, a groove and difference forming step using, as a mask, the photo-resist film 10 having the impurity implantation preventing resist pattern 10b and the alignment mark forming resist pattern 10a formed therein and selectively removing the entire thickness of the impurity implantation protecting film 2 that corresponds to the openings of the photo-resist 10 and removing a part of the alignment mark region insulating layer 9 below the removed impurity implantation protecting film 2 so as to form one or a plurality of grooves for becoming the alignment mark 6.

As described above, when the impurity implantation region 5 is formed, the alignment mark forming resist pattern 10a is exposed to light and formed, at the same time as the impurity implantation preventing resist pattern 10b, in the resist film 10 that is used for forming the impurity implantation preventing resist pattern 10b. Prior to or subsequent to the impurity implantation, the photo-resist film 10 is used as a mask, and the difference portion 2b is formed in the impurity implantation protecting film 2, and one or a plurality of grooves for becoming the alignment mark 6 is formed in the alignment mark region insulating layer 9 that is formed in the alignment mark forming region A at the same time as the element separation insulating layer. As such, the impurity implantation region 5 can be used as an alignment target layer. In other words, the impurity implantation region 5 and the alignment mark 6 are formed using the same resist film as a mask. Thus, the alignment precision can be improved, and this can accommodate a miniaturized semiconductor device and solid-state image capturing apparatus.

A part of the etching difference (difference portion 2b) processed when the alignment mark 6 is formed is present in the impurity implantation protecting film 2 in the active region B after the processing. However, when the impurity implantation step is continuously preformed, an impurity implantation condition is set such that the thickness of the impurity implantation protecting film 2 does not affect the semiconductor substrate 1 in the active region B nor the device characteristic even if the etching difference (difference portion 2b) is absent in the impurity implantation protecting film 2. Alternatively, a pattern layout can be designed such that the portion corresponding to the etching difference (difference portion 2b) is covered with the implantation impurity preventing photo-resist film 7 when the impurity implantation protecting film 2 is absent. More preferably, the entire impurity implantation protecting film 2 is removed from the semiconductor substrate 1, and a film having a film thickness considered as an impurity implantation protecting film is newly coated in a subsequent step.

Further, even if the impurity implantation protecting film 2 is absent in the etching difference (difference portion 2b) an impurity implantation can be performed after the etching process in the case where an impurity implantation condition is set such that the thickness of the impurity implantation protecting film 2 does not affect the semiconductor substrate 1 in the active region B nor the characteristic device and also in the case where the patterning shape of the alignment mark forming resist pattern 10b and the film thickness of the resist film after the etching process do not affect the formation of the impurity implantation region 5.

Further, when an alignment mark is formed in the alignment mark region insulating layer 9, it is possible to have a structure in which no impurity implantation protecting film 2 is provided on the alignment mark region insulating layer 9.

In Embodiment 1, the film thickness of the impurity implantation protecting film 2 is set in consideration that an etching process be completed within the impurity implantation protecting film 2 such that the thickness of the impurity implantation protecting film 2 does not affect the semiconductor substrate 1 in an impurity ion implantation step that uses the impurity implantation region 5 as an alignment target layer and also such that the thickness of the impurity implantation protecting film 2 does not affect the impurity implantation region 5 in a step of forming an alignment mark in the semiconductor substrate 1 that is performed by a known etching technique using, as a mask, an alignment mark forming photo-resist pattern resolved at the same time as a photo-resist pattern for forming the impurity implantation region 5. For example, as the impurity implantation protecting film 2, an oxide film or nitride film is coated by a known coating technique such that the film thickness thereof is between 50 Å (including 50 Å) and 2000 Å (including 2000 Å). In addition, in Embodiment 2, the photo-resist film 7 is used, and an etching condition having a sufficient difference in etching rate between the silicon substrate and the oxide film or the nitride film is set such that the thickness of the impurity implantation protecting film 2 does not affect the surface of the active region B nor the device characteristic when the alignment mark 6 is formed in the silicon substrate (semiconductor substrate 1). As such, the entire impurity implantation protecting film 2 at the opening of the impurity implantation preventing photo-resist pattern 7b can be removed. Further, in Embodiment 3, the photo-resist film 10 is used, and an etching condition having a sufficient difference in etching rate between the silicon substrate and the oxide film or the nitride film is set such that the thickness of the impurity implantation protecting film 2 does not affect the surface of the active region B nor the device characteristic when the alignment mark 6 is formed in the alignment mark region insulating layer 9. As such, the entire impurity implantation protecting film 2 at the opening of the impurity implantation preventing photo-resist pattern 10b can be removed.

Embodiments 4 and 5 will describe in detail an alignment method for performing an alignment using the alignment mark 6 formed according to Embodiments 1 to 3 and the alignment precision in such a case.

### Embodiment 4

Portion (a) of FIG. 2 and Portion (b) of FIG. 2 are each a longitudinal cross-sectional view showing an essential part in a step of manufacturing a semiconductor device for describing a case in which an alignment for another impurity implantation region is performed using the alignment mark 6 that is formed in the alignment mark forming step shown, for example, in Portion (d) of FIG. 1A.

As shown in Portion (a) of FIG. 2, another photo-resist film is newly coated on the semiconductor substrate 1, and an impurity implantation preventing photo-resist pattern 11b is formed so as to have an opening above the active region B for becoming another impurity implantation region 15 to be described later. In this case, an alignment is performed using the alignment mark 6 that is formed using the alignment mark forming photo-resist pattern 4a.

In Embodiment 4, as shown in Portion (b) of FIG. 2, in a lithography step of forming the impurity implantation region 5, only the alignment precision for the alignment mark 6 has to be considered. In Portion (b) of FIG. 2, D indicates a distance between the alignment mark 6 and the impurity implantation region 15. d indicates a misalignment tolerance range for the impurity implantation region 15.

The alignment mark 6 is formed based on the alignment mark forming photo-resist pattern 4a that is simultaneously created in the lithography step of forming the impurity implantation region 5 for becoming the alignment target layer. Therefore, a manufacturing process can be managed with a highly-precise alignment tolerance value that is equivalent to the value that is required for the most stringent alignment precision between steps.

### Embodiment 5

Portion (a) of FIG. 3 and Portion (b) of FIG. 3 are each a longitudinal cross-sectional view showing an essential part in a step of manufacturing a semiconductor device for describing a case in which an alignment between the impurity implantation region 5 and a wiring layer (process layer) formed in a subsequent step is performed using the alignment mark 6 that is formed in the alignment mark forming step shown, for example, in Portion (d) of FIG. 1A.

As shown in Portion (a) of FIG. 3, a semiconductor substrate/wiring film insulating inter-layer film 12 and a wiring film 13 are coated on the semiconductor substrate 1. A photo-resist film 14 is coated thereon. A wiring layer forming photo-resist pattern 14a is formed to cover, from the above, a wiring layer forming portion to be described layer. In this case, an alignment is performed using the alignment mark 6 that is formed using the alignment mark forming photo-resist pattern 4a.

In embodiment 5, as shown in Portion (b) of FIG. 3, in a lithography step for the wiring layer 13a that is formed in a step subsequent to the step of forming the impurity implantation region 5, only the alignment precision for the alignment mark 6 (propagation shape 6a of the alignment mark 6) has to be considered.

The alignment mark 6 is formed based on the alignment mark forming photo-resist pattern 4a that is simultaneously created in the lithography step of forming the impurity implantation region 5 for becoming the alignment target layer. Therefore, a manufacturing process can be managed with a highly-precise alignment tolerance value that is equivalent to the value that is required for the most stringent alignment precision between steps.

Further, a difference having one or a plurality of grooves for becoming the alignment mark 6 is propagated toward the upper side of the wiring film 13, so that the difference is formed on the top surface of the wiring film 13. Therefore, the alignment mark 6 can be used for a subsequent step, as necessary. Preferably, a layout and processing of the wiring film 13 is performed in consideration of a difference to be required, a width of alignment mark and an interval between grooves such that the difference of the propagation shape 6a of the alignment mark 6 does not disappear from the wiring film 13. Further, when the difference of the groove of the alignment mark 6 disappears from the upper side of the wiring layer 13a due to the limitation in the processing, the wiring film 13 on the alignment mark 6 can be removed to expose the grooves of the alignment mark 6 when the wring layer 13a is processed.

### Embodiment 6

Embodiment 6 will describe a case in detail in which the alignment mark forming method according to Embodiments 1 to 3 and the alignment method according to Embodiments 4 and 5 are applied to a method for manufacturing a CCD (charge-coupled device) solid-stat image capturing apparatus 50 as a semiconductor device.

Portion (a) of FIG. 4 to Portion (d) of FIG. 4 are each a longitudinal cross-sectional view showing a substrate portion for describing a step of manufacturing a solid-state image capturing apparatus according to Embodiment 6 of the present invention.

In the solid-state image capturing apparatus 50 according to Embodiment 6 shown in Portion (d) of FIG. 4, a P-type semiconductor well region 32 is formed in an N-type silicon substrate 31. A P-type semiconductor region 35 functioning as a reading gate region; a channel stop region 38; a P-type semiconductor active region 36 and an N-type semiconductor active region 37 thereabove functioning as a charge transfer region between the P-type semiconductor region 35 and the channel stop region 38; and an N-type impurity diffusion region 33 and a high-concentration P-type impurity diffusion region 34 at the top surface of the N-type impurity diffusion region 33 functioning as a photodiode section (PD section; photoelectric conversion section) for becoming a light receiving section are formed in respective predetermined regions of the P-type semiconductor well region 32.

An insulating film (e.g., SiO₂ film 39) is formed on the top surface of the P-type semiconductor well region 32. A Si₃N₄ film 40 of a gate section is formed on the SiO₂ film 39 to avoid a portion above the high-concentration P-type impurity diffusion region 34 of the PD section. A charge transfer electrode 41 is formed on the Si₃N₄ film 40. An inter-layer insulating film 42 is formed on the charge transfer electrode 41 to cover the charge transfer electrode 41.

Further, a light-shielding film 43 having an opening above the high-concentration P-type impurity diffusion layer 34 is formed on the inter-layer insulating film 42 such that the high-concentration P-type impurity diffusion layer 34 can receive light. An inter-layer insulating film 44 and a BPSG film 45, made from material such as PSG (phosphorus silicate glass), as a passivation film are formed on an entire substrate portion where the light-shielding film 43 is formed. Further, a microlens (not shown) is formed, and a color filter and the like are formed, as necessary.

Hereinafter, the method for manufacturing the CCD solid-state image capturing apparatus 50 will be described in the order of the steps shown in Portion (a) of FIG. 4 to Portion (b) of FIG. 4.

First, as shown in Portion (a) of FIG. 4, the P-type semiconductor well region 32 is formed on the N-type silicon substrate 31. Further, an insulating film (e.g., SiO₂ film 39) is formed on the top surface of the P-type semiconductor well region 32.

Next, N-type impurity ions and P-type impurity ions are selectively implanted in respective predetermined regions of the P-type semiconductor well region 32. As a result, as first to third impurity implantation regions, the P-type semiconductor region 35 functioning as the reading gate region, the channel stop region 38, and the P-type semiconductor active region 36 and the N-type semiconductor active region 37 thereabove functioning as the charge transfer region between the P-type semiconductor region 35 and the channel stop region 38 are formed, respectively.

The first to third impurity implantation regions are formed in the P-type semiconductor active region 36 and the N-type semiconductor active region 37 thereabove functioning as the charge transfer region, the channel stop region 38, and the P-type semiconductor region 35 functioning as the reading gate region, respectively, in an arbitrary order thereof. Embodiment 6 describes a case in which the P-type semiconductor active region 36 and the N-type semiconductor active region 37 that are the first impurity implantation region functioning as the charge transfer region are formed first, then the channel stop region 38 that is the second impurity implantation region is formed, and then the P-type semiconductor region 35 that is the third impurity implantation region functioning as the reading gate region is formed, in this order. Also, Embodiment 6 describes a case in which the alignment mark 6 is formed in the same manner as in the case of Embodiment 1. Alternatively, the alignment mark 6 can be formed in the same manner as in the case of Embodiments 2 and 3.

First, an impurity implantation protecting film 2 (herein, SiO₂ film 39) is coated. A photo-resist pattern is formed in the impurity implantation protecting film 2 such that an opening of a photo-resist pattern is located in the alignment mark forming region A. Next, the impurity implantation protecting film 2 below the opening of the photo-resist pattern is removed, and the photo-resist pattern is removed from the substrate 31 by O₂ plasma, sulfuric acid or the like.

Next, an impurity implantation preventing resist pattern having an opening above a region for becoming a first impurity implantation region is formed, and at the same time an alignment mark forming photo-resist pattern is formed in the alignment mark forming region A. The impurity preventing resist pattern and the alignment mark forming resist pattern are used as a mask, and impurity is implanted into the first impurity implantation region and the alignment mark forming region A.

Thereafter, the alignment mark forming photo-resist pattern 4a that is formed in a portion where the impurity implantation protecting film 2 is removed in the alignment mark forming region A is used as a mask, and a dry etching process is performed on the alignment mark forming region A of the semiconductor substrate 1 to form one or a plurality of grooves for becoming an alignment mark 6.

An alignment is performed using the one or the plurality of grooves of the alignment mark that is formed by the alignment mark forming method according to Embodiment 1, and a second impurity implantation region (channel stop region 38) is formed. The second impurity implantation region is different from the first impurity implantation region (charge transfer region; P-type semiconductor active region 36 and N-type semiconductor active region 37).

Further, an alignment is performed using the one or the plurality of grooves of the alignment mark, and a third impurity implantation region (P-type semiconductor region 35) is formed. The third impurity implantation region is different from the first impurity implantation region and the second impurity implantation region.

Next, as shown in Portion (b) of FIG. 4, an insulating film (e.g., Si₃N₄ film) is formed on the entire SiO₂ film 39. Thereafter, the Si₃N₄ film above the high-concentration P-type impurity diffusion region 34 of PD section (photoelectric conversion section) for becoming a light receiving section is selectively etched and removed. The Si₃N₄ film 40 of the gate section consists of the Si₃N₄ film 40 that remains without being removed.

The charge transfer electrode 41 is formed on the Si₃N₄ film 40 provided in the gate section. The inter-layer insulating film 42 is formed on the charge transfer electrode 41 to cover the charge transfer electrode 41. Also, in this case, an alignment is performed using the one or the plurality of grooves of the alignment mark that is formed by the alignment mark forming method, and the charge transfer electrode 41 is formed as a process film.

Further, as shown in Portion (c) of FIG. 4, the charge transfer electrode 41 is used as a part of a mask, and an alignment is performed using the one or the plurality of grooves of the alignment mark that is formed by the alignment mark forming method. For example, ions of phosphorus are implanted as an N-type impurity to form the N-type impurity diffusion region 33 of the PD section as a fourth impurity implantation region at a predetermined depth. For example, ions of boron are implanted to form the high-concentration P-type impurity diffusion region 34 of the PD section as the fourth impurity implantation region at the top surface layer of the N-type impurity diffusion region 33. A photoelectric conversion section of a light receiving section is configured by the PN junction between the N-type impurity diffusion region 33 and the P-type semiconductor well region 32, and the PN junction of the PD section between the N-type impurity diffusion region 33 and the high-concentration P-type impurity diffusion region 34.

Further, as shown in Portion (d) of FIG. 4, an alignment is performed using the one or the plurality of grooves of the alignment mark formed by the alignment mark forming method, and the light-shielding film 43, made from tungsten (W) film, titanium (Ti) film or the like, having an opening above the high-concentration P-type impurity diffusion layer 34 is formed on the inter-layer insulating film 42 to cover the charge transfer electrode 41 such that the high-concentration P-type impurity diffusion layer 34 can receive light.

The inter-layer insulating film 44 and the BPSG film 45, made from material such as PSG (phosphorus silicate glass), as a passivation film is formed in this order on an entire substrate portion where the light-shielding film 43 is formed, and then a microlens (not shown) is formed. As a result, the CCD solid-state image capturing apparatus 50 according to Embodiment 6 is manufactured.

More specifically, the method for manufacturing a CCD solid-state image capturing apparatus 50 according to Embodiment 6 includes: a second impurity region forming step of performing an alignment using the alignment mark 6 formed according to the alignment mark forming method according to the present invention, for example, shown in FIG. 1A, and using the impurity implantation preventing resist pattern 4b of the photo-resist film 4 as a mask to form the channel stop region 38 as a second impurity region that is different from the charge transfer region as the impurity implantation region 5 (first impurity region; P-type semiconductor active region 36 and N-type semiconductor active region 37) for becoming an alignment target layer; a third impurity region forming step of performing an alignment using the alignment mark 6 and forming a reading gate region (P-type semiconductor region 35) as a third impurity region; a charge transfer electrode forming step of performing an alignment using the alignment mark 6 and forming the charge transfer electrode 41 as a process layer on the first impurity implantation region, the second impurity implantation region and the third impurity implantation region via an insulating film; a fourth impurity region forming step of using the charge transfer electrode 41 as a part of mask and performing an alignment using the alignment mark 6 and forming a photodiode region as a light receiving region (fourth impurity region; PD section; N-type impurity diffusion region 33 and high-concentration P-type impurity diffusion region 34); and a light-shielding film forming step of performing an alignment using the alignment mark 6 and forming the light-shielding film 43 to cover the charge transfer electrode 41 from the above via an insulating film and to have an opening such that the photodiode region (PD section) can receive light.

As described above, according to Embodiment 6, as shown in FIG. 1A, for example, first, a photo-resist film as an impurity implantation preventing film is coated. Then, an etching process is performed using, as a mask, a photo-resist pattern in the photo-resist film 3 having the opening 3a formed in the alignment mark forming region A to remove the impurity implantation protecting film 2 of the alignment mark forming region A.

Next, the impurity implantation preventing photo-resist pattern 4b for the impurity implantation region 5 that is intended as an alignment target layer is formed, and at the same time the alignment mark forming photo-resist pattern 4a is formed. The photo-resist film 4 having the impurity implantation preventing photo-resist pattern 4b and the alignment mark forming photo-resist pattern 4a formed therein is used as a mask to perform a first impurity implantation. Thereafter, the photo-resist pattern 4a exposed on the semiconductor substrate 1 is used as a mask to process and form one or a plurality of grooves for becoming the alignment mark 6 in the semiconductor substrate 1. By using the location of the one or the plurality of grooves for becoming the alignment mark 6 as a reference, the other impurity implantation region 15 shown in FIG. 2 can be formed with excellent precision. As such, in a process of manufacturing a semiconductor device and a process of manufacturing a solid-state image capturing apparatus, an alignment mark forming method that can further reduce the tolerance value in alignment precision between the impurity implantation region 5 and the other impurity implantation region 15 and also between the impurity implantation region 5 and a process layer (e.g., charge transfer electrode 41 as a wiring layer, light-shielding film 43 or the like) formed in a subsequent step can be obtained.

The impurity implantation region is used as an alignment target layer, and thus the alignment precision can be improved at the time of lithography in a subsequent impurity implantation region forming step and a subsequent step of processing a wiring layer, a light-shielding film or the like to obtain a required device characteristic.

In Embodiment 6, a method for manufacturing a CCD solid-state image capturing apparatus 50 according to the present invention includes: a second impurity region forming step of performing an alignment using the alignment mark 6 formed according to the alignment mark forming method according to the present invention, and using the impurity implantation preventing resist pattern 4b of the photo-resist film 4 as a mask to form the channel stop region 38 as a second impurity region that is different from the charge transfer region as the impurity implantation region 5 (first impurity region; P-type semiconductor active region 36 and N-type semiconductor active region 37) for becoming an alignment target layer; a third impurity region forming step of performing an alignment using the alignment mark 6 and forming a reading gate region (P-type semiconductor region 35) as a third impurity region; a charge transfer electrode forming step of performing an alignment using the alignment mark 6 and forming the charge transfer electrode 41 as a process layer on the first impurity implantation region, the second impurity implantation region and the third impurity implantation region via an insulating film; a fourth impurity region forming step of using the charge transfer electrode 41 as a part of mask and performing an alignment using the alignment mark 6 and forming a photodiode region as a light receiving region (fourth impurity region; PD section; N-type impurity diffusion region 33 and high-concentration P-type impurity diffusion region 34); and a light-shielding film forming step of performing an alignment using the alignment mark 6 and forming the light-shielding film 43 to cover the charge transfer electrode 41 from the above via an insulating film and to have an opening such that the photodiode region (PD section) can receive light. However, the present invention is not limited to this. Alternatively, a method for manufacturing a CCD solid-state image capturing apparatus 50 can be configured as follows.

The charge transfer electrode 41 is not used as a mask when the fourth impurity region forming step is performed, and the fourth impurity region forming step of forming the photodiode region (PD section; N-type impurity diffusion region 33 and high-concentration P-type impurity diffusion region 34) can be performed prior to the formation of the charge transfer electrode 41 (prior to the charge transfer electrode forming step) and subsequent to the first to third impurity region forming steps. In this case, the first to fourth impurity implantation regions, the charge transfer region, the channel stop region, the reading gate region and the photodiode region are formed in an arbitrary order thereof. Thereafter, it is possible to perform: a charge transfer electrode forming step of performing an alignment using the alignment mark 6 and forming the charge transfer electrode 41 as a process layer on the first impurity implantation region, the second impurity implantation region and the third impurity implantation region via an insulating film; and subsequent to the charge transfer electrode forming step, a light-shielding film forming step of performing an alignment using the alignment mark 6 and forming the light-shielding film 43 to cover the charge transfer electrode 41 from the above via an insulating film and to have an opening such that the photodiode region (PD section; N-type impurity diffusion region 33 and high-concentration P-type impurity diffusion region 34) can receive light.

As described above, according to the present invention, as shown in FIG. 1A, first, the impurity implantation preventing film 2 is coated on the semiconductor substrate 1. Then, an etching process is performed using, as a mask, a pattern in the photo-resist film 3 having the opening 3a formed in the alignment mark forming region A to remove the impurity implantation protecting film 2 of the alignment mark forming region A. Next, the impurity implantation preventing photo-resist pattern 4b for the impurity implantation region 5 that is intended as an alignment target layer is formed, and at the same time the alignment mark forming photo-resist pattern 4a is exposed to light and formed. A first impurity implantation is performed using the photo-resist film. Thereafter, the alignment forming photo-resist pattern 4a having an opening above the semiconductor substrate 1 is used as a mask to process and form one or a plurality of grooves for becoming the alignment mark 6 in the semiconductor substrate 1. By using the alignment mark 6 as a reference and using the impurity implantation region 5 as an alignment target layer, it is possible to improve alignment precision between the step of forming of the impurity implantation region 15 and a subsequent step of processing a wiring layer, a light-shielding layer or the like.

The alignment mark forming method according to the present invention has been described with reference to Embodiments 1 to 3 as an example. However, the present invention is not limited to this. In other words, the present invention only has to include an alignment mark forming step of using an impurity implantation region as an alignment target layer and using the same resist film used for forming the impurity implantation region as a mask to form an alignment mark that is used when a patterning is performed in at least one of a subsequent impurity implantation step and a subsequent process layer forming step. In this manner, by using the same photo-resist film as a mask to form the impurity implantation region and the alignment mark, it is possible to implement the objective of the present invention to improve alignment precision and accommodate a miniaturized semiconductor device and solid-state image capturing apparatus. In this case, the alignment mark forming step only has to include, prior to the formation of the alignment mark 6, at least a protecting film forming step of forming a protecting film for protecting a top surface of the semiconductor substrate 1 that corresponds to the impurity implantation region 5 (impurity implantation protecting film 2 for protecting the surface of the semiconductor substrate 1 from becoming rough when the impurity is implanted).

In addition, Embodiments 1 to 3 have described the case in which a single resist film is used as a mask in the groove forming step according to Embodiments 1 to 3 to form one or a plurality of grooves as the alignment mark 6 in the alignment mark forming region A of the semiconductor substrate 1. However, the present invention is not limited to this. Alternatively, the groove can be any one of a single pole-shaped groove, a plurality of pole-shaped grooves arranged so as to be adjacent to each other, one or a plurality of lattice-shaped grooves and one or a plurality of holes (in the case where an outline of a predetermined symbol or shape is formed by a plurality of holes).

As described above, the present invention is exemplified by the use of its preferred Embodiments 1 to 6. However, the present invention should not be interpreted solely based on Embodiments 1 to 6 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 6 of the present invention. Furthermore, it is understood that any patent, any patent application and any references cited in the present specification should be incorporated by reference in the present specification in the same manner as the contents are specifically described therein.

### INDUSTRIAL APPLICABILITY

According to the present invention, in a field of: an alignment mark forming method in which an impurity implantation region can be used as an alignment target layer in order to reduce a tolerance value in alignment precision between impurity implantation regions and also to reduce a tolerance value in alignment precision between an impurity implantation region and a process layer (e.g., wiring layer, light-shielding film or the like) formed in a step subsequent to an impurity implantation step among steps of manufacturing a semiconductor device (e.g., transistor, photodiode and the like); an alignment method using the alignment mark forming method; and a semiconductor device manufacturing method and a solid-state image capturing apparatus manufacturing method for manufacturing a semiconductor device and a solid-state image capturing apparatus by performing an alignment using an alignment mark formed by using the alignment mark forming method, in a process of manufacturing a semiconductor device or a solid-state image capturing device, by using the same resist film as a mask to form an impurity implantation region and an alignment mark and using the impurity implantation region as an alignment target layer, it is possible to manage alignment precision between impurity implantation regions and also between an impurity implantation region and a process layer (e.g., wiring layer, light-shielding film or the like) formed in a subsequent step with a highly-precise alignment tolerance value that is equivalent to the value that is required for the most stringent alignment precision in a manufacturing process. Thus, it is possible to accommodate a miniaturized semiconductor device and solid-state image capturing apparatus.

In addition, since one or a plurality of grooves formed in a semiconductor substrate or an element separation insulating layer can be used as an alignment mark, it is possible to perform an alignment by various alignment methods, such as an alignment method for detecting the position of the alignment mark using scattered light from a difference portion as a detection signal waveform with respect to incident light from a light source for alignment, and an alignment method for detecting the position of the alignment mark using, as a detection signal waveform, light/dark observed at an edge portion of a difference using an image viewed from above the alignment mark portion.

Further, since only the alignment mark forming region has the openings, and portions other than the alignment mark forming region are covered with an impurity protecting film or a resist film, no groove is processed in a semiconductor substrate region in an active region where the processing of groove is not intended, or an etching condition can be selected such that it does not cause any damage to the semiconductor substrate and process the semiconductor substrate. As such, a required characteristic of semiconductor device or solid-state image capturing apparatus can be obtained.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. An alignment mark forming method comprising:
an alignment mark forming step of using an impurity implantation region as an alignment target layer and using, as a mask, the same resist film used for forming the impurity implantation region to form an alignment mark that is used when a patterning is performed in at least one of a subsequent impurity implantation step and a subsequent process layer forming step.

2. An alignment mark forming method according to claim 1, wherein the resist film includes a resist pattern for forming the alignment mark and a resist pattern for forming the impurity implantation region, the resist patterns being exposed to light and formed at the same time.

3. An alignment mark forming method according to claim 1, wherein prior to the formation of the alignment mark, the alignment mark forming step includes a protecting film forming step of forming a protecting film for protecting at least a top surface of a semiconductor substrate that corresponds to the impurity implantation region.

4. An alignment mark forming method according to claim 2, wherein prior to the formation of the alignment mark, the alignment mark forming step includes a protecting film forming step of forming a protecting film for protecting at least a top surface of a semiconductor substrate that corresponds to the impurity implantation region.

5. An alignment mark forming method according to claim 3, wherein the protecting film forming step includes:
a protecting film coating step of coating an impurity implantation protecting film on the semiconductor substrate; and
a protecting film removing step of removing the impurity implantation protecting film in an alignment mark forming region.

6. An alignment mark forming method according to claim 4, wherein the protecting film forming step includes:
a protecting film coating step of coating an impurity implantation protecting film on the semiconductor substrate; and
a protecting film removing step of removing the impurity implantation protecting film in an alignment mark forming region.

7. An alignment mark forming method according to claim 1, wherein the alignment mark forming step includes:
a resist pattern forming step of coating a resist film on the semiconductor substrate, and forming an impurity implantation preventing resist pattern having an opening above an active region for becoming the impurity implantation region and forming an alignment mark forming resist pattern having one or a plurality of openings above a region for becoming the alignment mark; and
prior to the impurity implantation step or subsequent to the impurity implantation step, a groove forming step of using, as a mask, the resist film having the impurity implantation preventing resist pattern and the alignment mark forming resist pattern formed therein to form one or a plurality of grooves as the alignment mark in an alignment mark forming region of the semiconductor substrate.

8. An alignment mark forming method according to claim 7, wherein the groove forming step forms a difference portion in the impurity implantation protecting film that corresponds to the impurity implantation preventing resist pattern.

9. An alignment mark forming method according to claim 7, wherein when the one or the plurality of grooves is formed, the semiconductor substrate in the impurity implantation region is covered with the impurity implantation protecting film.

10. An alignment mark forming method according to claim 8, wherein when the one or the plurality of grooves is formed, the semiconductor substrate in the impurity implantation region is covered with the impurity implantation protecting film.

11. An alignment mark forming method according to claim 1, wherein the alignment mark forming step includes:
a protecting film coating step of coating an impurity implantation protecting film on a semiconductor substrate;
a first resist pattern forming step of coating a resist film on the impurity implantation protecting film, and forming, in the resist film, an impurity implantation preventing resist pattern having an opening above an active region for becoming the impurity implantation region and forming an alignment mark forming resist pattern having one or a plurality of openings above a region for becoming the alignment mark;
prior to the impurity implantation step or subsequent to the impurity implantation step, a difference portion forming step of using, as a mask, the resist film having the impurity implantation preventing resist pattern and the alignment mark forming resist pattern formed therein to remove a part or the entirety of the impurity implantation protecting film that corresponds to an opening of the resist film so as to form a difference portion in the impurity implantation protecting film;
a resist film removing step of removing the resist film;
a second resist pattern forming step of newly coating another resist film on the semiconductor substrate and forming, in the other resist film, an alignment mark region forming resist pattern having one or a plurality of openings above a region for becoming the alignment mark; and
a groove forming step of using, as a mask, the resist film having the alignment mark region forming resist pattern formed therein and the impurity implantation protecting film having the alignment mark forming pattern formed therein to form one or a plurality of grooves as the alignment mark in an alignment mark forming region of the semiconductor substrate.

12. An alignment mark forming method according to claim 1, further comprising an insulating film forming step of forming an insulating layer on the semiconductor substrate for the purpose of separating elements,
the alignment mark forming step includes:
a protecting film coating step of coating an impurity implantation protecting film on the semiconductor substrate and the insulating layer;
a resist pattern forming step of coating a resist film on the impurity implantation protecting film, and forming an impurity implantation preventing resist pattern having an opening above an active region for becoming the impurity implantation region and forming an alignment mark forming resist pattern having one or a plurality of openings above a region for becoming the alignment mark in the insulating layer that is formed in an alignment mark forming region in the insulating film forming step; and
prior to the impurity implantation step or subsequent to the impurity implantation step, a groove forming step of using, as a mask, the resist film having the impurity implantation preventing resist pattern and the alignment mark forming resist pattern formed therein to selectively remove a part or the entirety of the impurity implantation protecting film that corresponds to an opening of the resist film and to remove a part of the insulating layer below the removed impurity implantation protecting film so as to form one or a plurality of groove portions for becoming the alignment mark.

13. An alignment mark forming method according to claim 1, further comprising an insulating film forming step of forming an insulating layer on the semiconductor substrate for the purpose of separating elements,
the alignment mark forming step includes:
a resist pattern forming step of coating a resist film on the semiconductor substrate, and forming an impurity implantation preventing resist pattern having an opening above an active region for becoming the impurity implantation region and forming an alignment mark forming resist pattern having one or a plurality of openings above a region for becoming the alignment mark in the insulating layer that is formed in an alignment mark forming region in the insulating layer forming step; and
prior to the impurity implantation step or subsequent to the impurity implantation step, a groove forming step of using, as a mask, the resist film having the impurity implantation preventing resist pattern and the alignment mark forming resist pattern formed therein to remove a part of the insulating layer that corresponds to an opening of the resist film so as to form one or a plurality of grooves for becoming the alignment mark.

14. An alignment mark forming method according to claim 5, wherein at least one of an oxide film and a nitride film is coated as the impurity implantation protecting film.

15. An alignment mark forming method according to claim 6, wherein at least one of an oxide film and a nitride film is coated as the impurity implantation protecting film.

16. An alignment mark forming method according to claim 8, wherein at least one of an oxide film and a nitride film is coated as the impurity implantation protecting film.

17. An alignment mark forming method according to claim 11, wherein at least one of an oxide film and a nitride film is coated as the impurity implantation protecting film.

18. An alignment mark forming method according to claim 12, wherein at least one of an oxide film and a nitride film is coated as the impurity implantation protecting film.

19. An alignment mark forming method according to claim 12, wherein at least one of an oxide film and a nitride film is coated as the insulating film.

20. An alignment mark forming method according to claim 13, wherein at least one of an oxide film and a nitride film is coated as the insulating film.

21. An alignment mark forming method according to claim 7, wherein the resist film is set so as to have a film thickness that is required to prevent a penetration of impurity when the impurity is implanted.

22. An alignment mark forming method according to claim 11, wherein the resist film is set so as to have a film thickness that is required to prevent a penetration of impurity when the impurity is implanted.

23. An alignment mark forming method according to claim 7, wherein the impurity implantation protecting film is coated so as to have a film thickness such that an etching be completed within the impurity implantation protecting film in the groove forming step or in the difference portion forming step.

24. An alignment mark forming method according to claim 11, wherein the impurity implantation protecting film is coated so as to have a film thickness such that an etching be completed within the impurity implantation protecting film in the groove forming step or in the difference portion forming step.

25. An alignment mark forming method according to claim 12, wherein the impurity implantation protecting film is coated so as to have a film thickness such that an etching be completed within the impurity implantation protecting film in the groove forming step or in the difference portion forming step.

26. An alignment mark forming method according to claim 7, wherein the impurity implantation protecting film is coated so as to have a film thickness such that the film thickness of the impurity implantation protecting film does not affect the semiconductor substrate nor a device characteristic even if the impurity implantation protecting film is removed in the groove forming step or in the difference portion forming step and thus becomes thinner.

27. An alignment mark forming method according to claim 11, wherein the impurity implantation protecting film is coated so as to have a film thickness such that the film thickness of the impurity implantation protecting film does not affect the semiconductor substrate nor a device characteristic even if the impurity implantation protecting film is removed in the groove forming step or in the difference portion forming step and thus becomes thinner.

28. An alignment mark forming method according to claim 12, wherein the impurity implantation protecting film is coated so as to have a film thickness such that the film thickness of the impurity implantation protecting film does not affect the semiconductor substrate nor a device characteristic even if the impurity implantation protecting film is removed in the groove forming step or in the difference portion forming step and thus becomes thinner.

29. An alignment mark forming method according to claim 7, wherein the impurity implantation protecting film is coated such that a film thickness thereof is between 50 Å (including 50 Å) and 2000 Å (including 2000 Å).

30. An alignment mark forming method according to claim 11, wherein the impurity implantation protecting film is coated such that a film thickness thereof is between 50 Å (including 50 Å) and 2000 Å (including 2000 Å).

31. An alignment mark forming method according to claim 12, wherein the impurity implantation protecting film is coated such that a film thickness thereof is between 50 Å (including 50 Å) and 2000 Å (including 2000 Å).

32. An alignment mark forming method according to claim 8, wherein an etching condition is set such that a film thickness of the impurity implantation protecting film to be removed is between 10% (including 10%) and 100% (including 100%) of the entire film thickness of the impurity implantation protecting film.

33. An alignment mark forming method according to claim 11, wherein an etching condition is set such that a film thickness of the impurity implantation protecting film to be removed is between 10% (including 10%) and 100% (including 100%) of the entire film thickness of the impurity implantation protecting film.

34. An alignment mark forming method according to claim 12, wherein an etching condition is set such that a film thickness of the impurity implantation protecting film to be removed is between 10% (including 10%) and 100% (including 100%) of the entire film thickness of the impurity implantation protecting film.

35. An alignment mark forming method according to claim 8, wherein the formation of the difference portion in the impurity implantation protecting film is performed by a wet etching technique and/or a dry etching technique such that a sufficient difference in etching rate between the impurity implantation protecting film and the semiconductor substrate is obtained,
a type, concentration and liquid immersion time of an etching liquid are set in the wet etching technique, and
a vacuum degree, a gas mixing ratio, a gas flow volume and a plasma-applied voltage are set in the dry etching technique.

36. An alignment mark forming method according to claim 11, wherein the formation of the difference portion in the impurity implantation protecting film is performed by a wet etching technique and/or a dry etching technique such that a sufficient difference in etching rate between the impurity implantation protecting film and the semiconductor substrate is obtained,
a type, concentration and liquid immersion time of an etching liquid are set in the wet etching technique, and
a vacuum degree, a gas mixing ratio, a gas flow volume and a plasma-applied voltage are set in the dry etching technique.

37. An alignment mark forming method according to claim 12, wherein the formation of the difference portion in the impurity implantation protecting film is performed by a wet etching technique and/or a dry etching technique such that a sufficient difference in etching rate between the impurity implantation protecting film and the semiconductor substrate is obtained,
a type, concentration and liquid immersion time of an etching liquid are set in the wet etching technique, and
a vacuum degree, a gas mixing ratio, a gas flow volume and a plasma-applied voltage are set in the dry etching technique.

38. An alignment mark forming method according to claim 7, wherein after the formation of the alignment mark, the entire impurity implantation protecting film is removed from the semiconductor substrate, and an impurity implantation protecting film is newly coated for a subsequent impurity implantation step.

39. An alignment mark forming method according to claim 11, wherein after the formation of the alignment mark, the entire impurity implantation protecting film is removed from the semiconductor substrate, and an impurity implantation protecting film is newly coated for a subsequent impurity implantation step.

40. An alignment mark forming method according to claim 12, wherein after the formation of the alignment mark, the entire impurity implantation protecting film is removed from the semiconductor substrate, and an impurity implantation protecting film is newly coated for a subsequent impurity implantation step.

41. An alignment mark forming method according to claim 11, wherein the second resist pattern forming step exposes to light and develops the alignment mark forming region to form a pattern in the other resist film and uses, as a mask, the other resist film having the resolved alignment mark forming pattern to expose the alignment mark forming pattern formed in the impurity implantation protecting film.

42. An alignment mark forming method according to claim 11, wherein the second resist pattern forming step forms the other resist pattern such that it covers the semiconductor substrate in the impurity implantation region.

43. An alignment mark forming method according to claim 7, wherein in the groove forming step, a depth of the groove is set in consideration of a difference in etching rate between the impurity implantation protecting film and the semiconductor substrate such that a film thickness of greater than or equal to a predetermined film thickness of the impurity implantation protecting film remains on the semiconductor substrate and does not adversely affect a surface of the semiconductor substrate for becoming an active region nor a device characteristic.

44. An alignment mark forming method according to claim 11, wherein in the groove forming step, a depth of the groove is set in consideration of a difference in etching rate between the impurity implantation protecting film and the semiconductor substrate such that a film thickness of greater than or equal to a predetermined film thickness of the impurity implantation protecting film remains on the semiconductor substrate and does not adversely affect a surface of the semiconductor substrate for becoming an active region nor a device characteristic.

45. An alignment mark forming method according to claim 12, wherein in the groove forming step, a depth of the groove is set in consideration of a difference in etching rate between the impurity implantation protecting film and the semiconductor substrate such that a film thickness of greater than or equal to a predetermined film thickness of the impurity implantation protecting film remains on the semiconductor substrate and does not adversely affect a surface of the semiconductor substrate for becoming an active region nor a device characteristic.

46. An alignment mark forming method according to claim 11, wherein in the groove forming step, a depth of the groove is set in consideration of a difference in etching rate between the impurity implantation protecting film and the semiconductor substrate such that the impurity implantation protecting film remains on the semiconductor substrate other than the grooves in the alignment mark forming region so as to have a film thickness of greater than or equal to a predetermined film thickness or an exact entirety of the impurity implantation protecting film is removed.

47. An alignment mark forming method according to claim 11, wherein in the groove forming step, an etching difference is set in consideration of a difference in etching rate between the impurity implantation protecting film and the semiconductor substrate such that the impurity implantation protecting film remains on the semiconductor substrate other than the grooves in the alignment mark forming region so as to have a film thickness of greater than or equal to a predetermined film thickness or an exact entirety of the impurity implantation protecting film is removed.

48. An alignment mark forming method according to claim 7, wherein among a depth and width of the groove and an interval between the grooves, at least the depth of the groove is set such that the one or the plurality of grooves is reflected and appears on a surface of a process layer that is coated and processed in a step subsequent to the groove forming step.

49. An alignment mark forming method according to claim 11, wherein among a depth and width of the groove and an interval between the grooves, at least the depth of the groove is set such that the one or the plurality of grooves is reflected and appears on a surface of a process layer that is coated and processed in a step subsequent to the groove forming step.

50. An alignment mark forming method according to claim 7, wherein in the groove forming step, the depth of the groove is set between 5 nm (including 5 nm) and 150 nm (150 nm).

51. An alignment mark forming method according to claim 11, wherein in the groove forming step, the depth of the groove is set between 5 nm (including 5 nm) and 150 nm (150 nm).

52. An alignment mark forming method according to claim 50, wherein in the groove forming step, the depth of the groove is set between 40 nm (including 40 nm) and 80 nm (80 nm).

53. An alignment mark forming method according to claim 51, wherein in the groove forming step, the depth of the groove is set between 40 nm (including 40 nm) and 80 nm (80 nm).

54. An alignment mark forming method according to claim 7, wherein when the shape of the groove is not reflected and thus does not appear on a surface of a process layer to be coated and processed in a step subsequent to the groove forming step, a portion of the process layer that is located above the groove is removed to expose the groove.

55. An alignment mark forming method according to claim 11, wherein when the shape of the groove is not reflected and thus does not appear on a surface of a process layer to be coated and processed in a step subsequent to the groove forming step, a portion of the process layer that is located above the groove is removed to expose the groove.

56. An alignment mark forming method according to claim 12, wherein when the shape of the groove is not reflected and thus does not appear on a surface of a process layer to be coated and processed in a step subsequent to the groove forming step, a portion of the process layer that is located above the groove is removed to expose the groove.

57. An alignment mark forming method according to claim 7, wherein in the groove forming step, an etching condition is set such that an etching rate for each of the semiconductor substrate and the impurity implantation protecting film is taken into consideration and also such that a film thickness of the impurity implantation protecting film does not affect a surface of the semiconductor substrate for becoming an active region nor a device characteristic.

58. An alignment mark forming method according to claim 11, wherein in the groove forming step, an etching condition is set such that an etching rate for the alignment mark forming pattern, transcribed in the impurity implantation protecting film, with respect to the semiconductor substrate is taken into consideration and also such that a film thickness of the impurity implantation protecting film does not affect a surf ace of the semiconductor substrate for becoming an active region in the difference portion forming step nor a device characteristic.

59. An alignment mark forming method according to claim 12, wherein in the groove forming step, an etching condition is set such that an etching rate for each of the impurity implantation protecting film and the insulating film with respect to the semiconductor substrate is taken into consideration and also such that a film thickness of the impurity implantation protecting film does not affect a surface of the semiconductor substrate for becoming an active region nor a device characteristic.

60. An alignment mark forming method according to claim 13, wherein in the groove forming step, an etching condition is set such that an etching rate for the insulating film with respect to the semiconductor substrate is taken into consideration and also such that a film thickness of the impurity implantation protecting film does not affect a surface of the semiconductor substrate for becoming an active region nor a device characteristic.

61. An alignment mark forming method according to claim 7, wherein the groove is at least one of a single pole-shaped groove, a plurality of pole-shaped grooves arranged so as to be adjacent to each other, one or a plurality of lattice-shaped grooves and one or a plurality of holes.

62. An alignment mark forming method according to claim 11, wherein the groove is at least one of a single pole-shaped groove, a plurality of pole-shaped grooves arranged so as to be adjacent to each other, one or a plurality of lattice-shaped grooves and one or a plurality of holes.

63. An alignment mark forming method according to claim 12, wherein the groove is at least one of a single pole-shaped groove, a plurality of pole-shaped grooves arranged so as to be adjacent to each other, one or a plurality of lattice-shaped grooves and one or a plurality of holes.

64. An alignment mark forming method according to claim 13, wherein the groove is at least one of a single pole-shaped groove, a plurality of pole-shaped grooves arranged so as to be adjacent to each other, one or a plurality of lattice-shaped grooves and one or a plurality of holes.

65. An alignment method for performing an alignment on at least one of an impurity implantation region and a process layer that are formed after the alignment mark forming step, by using the alignment mark formed by the alignment mark forming method according to claim 1.

66. A method for manufacturing a semiconductor device comprising the step of using the alignment mark formed by the alignment mark forming method according to claim 1 and using the impurity implantation preventing resist pattern as a mask to form at least one of another impurity implantation region and a process layer, the other impurity implantation region being different from the impurity implantation region with ions of impurity implanted therein.

67. A method for manufacturing a solid-state image capturing apparatus comprising:
a second impurity region forming step of performing an alignment using the alignment mark formed by the alignment mark forming method according to claim 1 and using the impurity implantation preventing resist pattern formed in the resist film as a mask to form a second impurity region that is different from the first impurity region with the impurity implanted therein; and
a third impurity implantation region forming step of performing an alignment using the alignment mark and forming a third impurity region,
wherein
the first to third impurity implantation regions are formed in a charge transfer region, a channel stop region and a reading gate region, respectively, in an arbitrary order thereof.

68. A method for manufacturing a solid-state image capturing apparatus according to claim 67, further comprising:
a charge transfer electrode forming step of performing an alignment using the alignment mark and forming a charge transfer electrode as a process film on the first impurity implantation region, the second impurity implantation region and the third impurity implantation region via an insulating film; and
a fourth impurity region forming step of performing an alignment using the alignment mark and using the charge transfer electrode as a part of a mask to form a photodiode region.

69. A method for manufacturing a solid-state image capturing apparatus according to claim 68, further comprising: subsequent to the fourth impurity region forming step,
a light-shielding film forming step of performing an alignment using the alignment mark and covering the charge transfer electrode via the insulating film and forming a light-shielding film having an opening above the photodiode region such that the photodiode region can receive light.

70. A method for manufacturing a solid-state image capturing apparatus comprising:
a second impurity region forming step of performing an alignment using the alignment mark formed by the alignment mark forming method according to claim 1 and using the impurity implantation preventing resist pattern formed in the resist film as a mask to form a second impurity region that is different from a first impurity region with impurity implanted therein;
a third impurity implantation region forming step of performing an alignment using the alignment mark and forming a third impurity region; and
a fourth impurity region forming step of performing an alignment using the alignment mark and forming a fourth impurity region,
wherein
the first to fourth impurity implantation regions are formed in a charge transfer region, a channel stop region, a reading gate region and a photodiode region, respectively, in an arbitrary order thereof.

71. A method for manufacturing a solid-state image capturing apparatus according to claim 70, further comprising:
a charge transfer electrode forming step of performing an alignment using the alignment mark and forming a charge transfer electrode as a process film on the first impurity implantation region, the second impurity implantation region and the third impurity implantation region via an insulating film.

72. A method for manufacturing a solid-state image capturing apparatus according to claim 71, further comprising: subsequent to the charge transfer electrode forming step,
a light-shielding film forming step of performing an alignment using the alignment mark and covering the charge transfer electrode via the insulating film and forming a light-shielding film having an opening above the photodiode region such that the photodiode region can receive light.

73. A method for manufacturing a solid-state image capturing apparatus according to claim 67, wherein in the impurity region forming step, an impurity implantation condition is set such that a film thickness of the impurity implantation protecting film does not affect the semiconductor substrate nor a device characteristic even if a part of the impurity implantation protecting film is removed in the alignment mark forming step and thus becomes thinner or the impurity implantation protecting film is removed in the alignment mark forming step and thus a portion of the impurity implantation protecting film does not exist.

74. A method for manufacturing a solid-state image capturing apparatus according to claim 67, wherein the impurity region forming step sets ion species, implantation volume, implantation energy and implantation angle in accordance with a required device characteristic.

75. A method for manufacturing a solid-state image capturing apparatus according to claim 70, wherein in the impurity region forming step, an impurity implantation condition is set such that a film thickness of the impurity implantation protecting film does not affect the semiconductor substrate nor a device characteristic even if a part of the impurity implantation protecting film is removed in the alignment mark forming step and thus becomes thinner or the impurity implantation protecting film is removed in the alignment mark forming step and thus a portion of the impurity implantation protecting film does not exist.

76. A method for manufacturing a solid-state image capturing apparatus according to claim 70, wherein the impurity region forming step sets ion species, implantation volume, implantation energy and implantation angle in accordance with a required device characteristic.
